(19) United States
(12) Patent Application Publication
(10) Pub. No.: US 2024/0196708 A1
(43) Pub. Date: Jun. 13, 2024

(54) LIGHT-EMITTING SUBSTRATE AND LIGHT-EMITTING DEVICE

(71) Applicant: BOE TECHNOLOGY GROUP CO., LTD., Beijing (CN)

(72) Inventors: Haiyan SUN, Beijing (CN); Xiaojin ZHANG, Beijing (CN); Siqi WANG, Beijing (CN); Dan WANG, Beijing (CN)

(73) Assignee: BOE TECHNOLOGY GROUP CO., LTD., Beijing (CN)

(21) Appl. No.: 17/908,095

(22) PCT Filed: Sep. 29, 2021
(86) PCT No.: PCT/CN2021/121760

§ 371 Date: Aug. 30, 2022

(51) Int. Cl. H10K 59/80; H10K 59/126; H10K 59/38; H10K 102/00

(52) U.S. Cl. CPC H10K 59/879; H10K 59/126; H10K 59/38; H10K 2102/351

(57) ABSTRACT

A light-emitting substrate includes a substrate, a plurality of sub-pixels, a first light extraction layer and a second light extraction layer. Each sub-pixel includes a light-emitting element and a light conversion pattern disposed on a light-exit side of the light-emitting element. The plurality of sub-pixels include at least one first sub-pixel. The first light extraction layer is disposed on a side of the first sub-pixel away from the light-emitting element, and at least located in a region where the at least one first sub-pixel is located. The first light extraction layer includes first transparent substrate(s) and optically active substances added in each first transparent substrate. The second light extraction layer is disposed on a side of the first light extraction layer away from the light-emitting element. A refractive index of the second light extraction layer is smaller than a refractive index of the first light extraction layer.

### CROSS-REFERENCE TO RELATED APPLICATION

This application is a national phase entry under 35 USC 371 of International Patent Application No. PCT/CN2021/121760, filed on Sep. 29, 2021, which is incorporated herein by reference in its entirety.

### TECHNICAL FIELD

The present disclosure relates to the field of lighting and display technologies, and in particular, to a light-emitting substrate and a light-emitting device.

### BACKGROUND

Compared with organic light-emitting diode (OLED) luminescent devices, quantum dot light-emitting diode (QLED) luminescent devices have properties such as higher theoretical luminous efficiency, adjustable colors, wider color gamut, better color saturation and vividness, and lower energy costs.

### SUMMARY

In an aspect, a light-emitting substrate is provided. The light-emitting substrate includes: a substrate, a plurality of sub-pixels disposed on the substrate, a first light extraction layer and a second light extraction layer. Each sub-pixel includes a light-emitting element disposed on the substrate and a light conversion pattern disposed on a light-exit side of the light-emitting element, the light-emitting element is configured to emit light of a first color. The plurality of sub-pixels include at least one first sub-pixel, a light conversion pattern included in a respective one of the at least one first sub-pixel is a first light conversion pattern, and the first light conversion pattern is configured to convert the light of the first color emitted by a light-emitting element located in a same sub-pixel as the first light conversion pattern into light of a second color. The first light extraction layer is disposed on a side of the first light conversion pattern away from the light-emitting element, and at least located in a region where the at least one first sub-pixel is located; the first light extraction layer includes at least one first transparent substrate and optically active substances added in each first transparent substrate, the optically active substances are selected from materials that are capable of selectively reflecting the light of the first color. The second light extraction layer is disposed on a side of the first light extraction layer away from the light-emitting element, a refractive index of the second light extraction layer is smaller than a refractive index of the first light extraction layer, and the second light extraction layer is configured to change an exit angle of light exiting from the first light extraction layer.

In some embodiments, the first light extraction layer has a single-layer structure. Alternatively, the first light extraction layer includes a first sub-layer and a second sub-layer that are sequentially stacked in a direction away from the light-emitting elements; the first sub-layer and the second sub-layer each include the optically active substances, and chirality of the optically active substances included in the first sub-layer is opposite to chirality of the optically active substances included in the second sub-layer.

In some embodiments, the optically active substances are liquid crystal material. Alternatively, the optically active substances include liquid crystal materials and chiral auxiliaries.

In some embodiments, in a case where the first light extraction layer includes a first sub-layer and a second sub-layer, the first sub-layer includes a first transparent substrate and optically active substances added in the first transparent substrate, the second sub-layer includes another first transparent substrate and optically active substances added in the another first transparent substrate, and the optically active substances included in the first sub-layer and the optically active substances included in the second sub-layer are each liquid crystal materials, and the first transparent substrate included in the first sub-layer and the another first transparent substrate included in the second sub-layer are made of a same material or different materials. In a case where the first light extraction layer includes the first sub-layer and the second sub-layer, the first sub-layer includes the first transparent substrate and the optically active substances added in the first transparent substrate, the second sub-layer includes the another first transparent substrate and the optically active substances added in the another first transparent substrate, and the optically active substances included in the first sub-layer and the optically active substances included in the second sub-layer each include liquid crystal materials and chiral auxiliaries, the first transparent substrate included in the first sub-layer and the another first transparent substrate included in the second sub-layer are made of a same material or different materials, and liquid crystal materials included in the first sub-layer and liquid crystal materials included in the second sub-layer are same or different.

In some embodiments, the plurality of sub-pixels further include at least one second sub-pixel, a light conversion pattern included in a respective one of the at least one second sub-pixel is a second light conversion pattern; the second light conversion pattern includes a second transparent substrate and scattering particles added in the second transparent substrate. In a case where the first light extraction layer has a single-layer structure, the first light extraction layer has a first pattern, a first region is located within an orthographic projection of the first pattern on the substrate, and the orthographic projection of the first pattern on the substrate is located outside a second region. In a case where the first light extraction layer includes the first sub-layer and the second sub-layer, the first sub-layer has a second pattern, and the second sub-layer has a third pattern; the first region is located within an orthographic projection of at least one of the second pattern and the third pattern on the substrate, and orthographic projections of the second pattern and the third pattern on the substrate are located outside the second region. The first region is a region where other sub-pixels in the plurality of sub-pixels except the at least one second sub-pixel are located, and the second region is a region where the at least one second sub-pixel is located.

In some embodiments, in a case where the first light extraction layer includes a first sub-layer and a second sub-layer, an orthographic projection of the first sub-layer on the substrate is located within an orthographic projection of the second sub-layer on the substrate.

In some embodiments, in a case where the first light extraction layer has a single-layer structure, the refractive index of the first light extraction layer is greater than or equal to a refractive index of at least one light conversion pattern in a region where the first light extraction layer is located. In a case where the first light extraction layer includes a first sub-layer and a second sub-layer, refractive indices of both the first sub-layer and the second sub-layer are greater than or equal to the refractive index of the at least one light conversion pattern in the region where the first light extraction layer is located.

In some embodiments, in a case where the first light extraction layer has a single-layer structure, the first light extraction layer includes a first surface proximate to the substrate, a second surface away from the substrate, and third surfaces each connected to the first surface and the second surface; an included angle between a third surface and the first surface is greater than or equal to 30 degrees and less than or equal to 150 degrees. In a case where the first light extraction layer includes a first sub-layer and a second sub-layer, the first sub-layer and the second sub-layer each include a fourth surface proximate to the substrate, a fifth surface away from the substrate, and sixth surfaces each connected to the fourth surface and the fifth surface, an included angle between a sixth surface of the first sub-layer and the fourth surface of the first sub-layer is greater than or equal to 30 degrees and less than or equal to 150 degrees, and an included angle between a sixth surface of the second sub-layer and the fourth surface of the second sub-layer is greater than or equal to 30 degrees and less than or equal to 150 degrees.

In some embodiments, the second light extraction layer has a single-layer structure. Alternatively, the second light extraction layer includes a third sub-layer and a fourth sub-layer that are sequentially arranged in a direction away from the substrate, a refractive index of the third sub-layer is smaller than the refractive index of the first light extraction layer, and a refractive index of the fourth sub-layer is smaller than the refractive index of the third sub-layer.

In some embodiments, in a case where the second light extraction layer has the single-layer structure, the second light extraction layer is provided with a first protrusion thereon corresponding to a region between every two adjacent sub-pixels; the first protrusion is configured to change the exit angle of the light exiting from the first light extraction layer. In a case where the second light extraction layer includes the third sub-layer and the fourth sub-layer, at least one of the third sub-layer and the fourth sub-layer is provided with a second protrusion thereon corresponding to the region between every two adjacent sub-pixels; the second protrusion is configured to change the exit angle of the light exiting from the first light extraction layer.

In some embodiments, the light-emitting substrate further includes a black matrix. In the case where the second light extraction layer has the single-layer structure, the black matrix is disposed between the first light extraction layer and the second light extraction layer, so that the second light extraction layer is provided with the first protrusion thereon corresponding to the region between every two adjacent sub-pixels. In the case where the second light extraction layer includes the third sub-layer and the fourth sub-layer, the black matrix is disposed between the third sub-layer and the first light extraction layer, so that the third sub-layer is provided with the second protrusion thereon corresponding to the region between every two adjacent sub-pixels; alternatively, the black matrix is disposed between the third sub-layer and the fourth sub-layer, so that the fourth sub-layer is provided with the second protrusion thereon corresponding to the region between every two adjacent sub-pixels.

In some embodiments, the light-emitting substrate further includes a pixel defining layer. The pixel defining layer defines a plurality of openings, and each opening corresponds to a region where a sub-pixel is located. An orthographic projection of the black matrix on the substrate is located within an orthographic projection of the pixel defining layer on the substrate, and an orthographic projection of a border of the black matrix on the substrate and an orthographic projection of a border of the pixel defining layer on the substrate have a space therebetween.

In some embodiments, in the case where the second light extraction layer has the single-layer structure, a portion of the black matrix located between every two adjacent sub-pixels includes a seventh surface in contact with the first light extraction layer and an eighth surface in contact with the second light extraction layer, and an included angle between the seventh surface and the eighth surface is greater than 30 degrees. In a case where the second light extraction layer includes the third sub-layer and the fourth sub-layer, and the black matrix is located between the third sub-layer and the first light extraction layer, the portion of the black matrix located between every two adjacent sub-pixels includes the seventh surface in contact with the first light extraction layer and the eighth surface in contact with the third sub-layer and the included angle between the seventh surface and the eighth surface is greater than 30 degrees. In a case where the second light extraction layer includes the third sub-layer and the fourth sub-layer, and the black matrix is located between the third sub-layer and the fourth sub-layer, the portion of the black matrix located between every two adjacent sub-pixels includes the seventh surface in contact with the third sub-layer and the eighth surface in contact with the fourth sub-layer, and the included angle between the seventh surface and the eighth surface is greater than 30 degrees.

In some embodiments, longitudinal sections of portions, of the black matrix, each located between every two adjacent sub-pixels are in a same shape or different shapes, and the shape is a rectangle, a triangle, an arch, a trapezoid or an inverted trapezoid; a longitudinal section is perpendicular to a surface where the substrate is located.

In some embodiments, for light with a wavelength in a range of 380 nm to 780 nm, inclusive, absorbance per micron of the black matrix is greater than 0.5/μm.

In some embodiments, the second light extraction layer includes the third sub-layer and the fourth sub-layer, and a difference between the refractive index of the third sub-layer and the refractive index of the fourth sub-layer is greater than 0.2.

In some embodiments, the second light extraction layer includes the third sub-layer and the fourth sub-layer, a thickness of the third sub-layer is greater than 3.5 μm, and a thickness of the fourth sub-layer is less than 2.5 μm.

In some embodiments, in a case where the first light extraction layer has a single-layer structure, for light with a wavelength in a range of 400 nm to 500 nm, inclusive, a light transmittance of the first light extraction layer is in a range of 40% to 70%, inclusive; and for light with a wavelength greater than 500 nm, a light transmittance of the first light extraction layer is greater than 90%. In a case where the first light extraction layer includes a first sub-layer and a second sub-layer, for the light with the wavelength in the range of 400 nm to 500 nm, inclusive, light transmittances of the first sub-layer and the second sub-layer are both in a range of 40% to 70%, inclusive, and a light transmittance of at least one of the first sub-layer and the second sub-layer is greater than 50%; and for the light with the wavelength greater than 500 nm, light transmittances of the first sub-layer and the second sub-layer are both greater than 90%.

In some embodiments, the first light extraction layer includes the first sub-layer and the second sub-layer, and a difference between a center wavelength of light transmitted by the first sub-layer and a center wavelength of light transmitted by the second sub-layer is less than 20 nm.

In some embodiments, the plurality of sub-pixels further include at least one third sub-pixel, a light conversion pattern included in a respective one of the at least one third sub-pixel is a third light conversion pattern; the third light conversion pattern is configured to convert the light of the first color emitted by a light-emitting element located in a same sub-pixel as the third light conversion pattern into light of a third color; the first color, the second color and the third color are three primary colors. The first light conversion pattern and the third light conversion pattern each include a third transparent substrate and quantum dot light-emitting materials dispersed in a respective third transparent substrate.

In some embodiments, the first light conversion pattern and the third light conversion pattern each further include scattering particles dispersed in the respective third transparent substrate.

In some embodiments, the light-emitting substrate further includes a filter film. The filter film is disposed on a side of the second light extraction layer away from the substrate, the filter film includes a plurality of filter units, and each filter unit is disposed in a region where a sub-pixel is located. The plurality of sub-pixels further include at least one second sub-pixel, a light conversion pattern included in a respective one of the at least one second sub-pixel is a second light conversion pattern. For a filter unit located in a region where a second sub-pixel is located, a difference between a peak value of a transmission spectrum of the filter unit and a peak value of light emitted by a light-emitting element included in the second sub-pixel is not more than 5 nm, and a half-peak width of the transmission spectrum of the filter unit is not less than a half-peak width of the light emitted by the light-emitting element included in the second sub-pixel. For another filter unit located in a region where a first sub-pixel is located, a difference between a peak value of a transmission spectrum of the another filter unit and a peak value of light exiting from the first light conversion pattern is not more than 5 nm, and a half-peak width of the transmission spectrum of the another filter unit is not less than a half-peak width of the light exiting from the first light conversion pattern. For yet another filter unit located in a region where a third sub-pixel is located, a difference between a peak value of a transmission spectrum of the yet another filter unit and a peak value of light exiting from the third light conversion pattern is not more than 5 nm, and a half-peak width of the transmission spectrum of the yet another filter unit is not less than a half-peak width of the light exiting from the third light conversion pattern.

In some embodiments, the light-emitting element includes a light-emitting layer, and the light-emitting layer includes a first light-emitting sub-layer, a charge generation layer and a second light-emitting sub-layer that are sequentially stacked in a direction away from the substrate; luminescence spectrums of the first light-emitting sub-layer and the second light-emitting sub-layer are both in a range of 400 nm to 500 nm, inclusive.

In another aspect, a light-emitting device is provided. The light-emitting device includes the light-emitting substrate described above.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings in the following description may be regarded as schematic diagrams, but are not limitations on actual sizes of products, actual processes of methods and actual timings of signals involved in the embodiments of the present disclosure.

FIG. 1A is a sectional view showing a structure of a light-emitting substrate provided in the related art;

FIG. 1B is a top view showing a structure of a light-emitting substrate, in accordance with some embodiments;

FIG. 1C is an equivalent circuit diagram of a 3T1C structure, in accordance with some embodiments;

FIG. 1D is a sectional view showing a structure of a light-emitting element, in accordance with some embodiments;

FIG. 2A is a sectional view showing a structure of another light-emitting substrate, in accordance with some embodiments;

FIG. 2B is a diagram showing a structure of a first light extraction layer reflecting light, in accordance with some embodiments;

FIG. 2C is a sectional view showing a structure of another light-emitting substrate, in accordance with some embodiments;

FIG. 2D is a diagram showing a structure of another first light extraction layer reflecting light, in accordance with some embodiments;

FIG. 2E is a transmission spectrum diagram of a first sub-layer and a second sub-layer, in accordance with some embodiments;

FIG. 2F is a sectional view showing a structure of yet another light-emitting substrate, in accordance with some embodiments;

FIG. 2G is a diagram showing a structure of a first protrusion reflecting light in FIG. 2F, in accordance with some embodiments;

FIG. 2H is an enlarged view of the region D in FIG. 2G, in accordance with some embodiments;

FIG. 2I is a sectional view showing a structure of yet another light-emitting substrate, in accordance with some embodiments;

FIG. 2J is a diagram showing a structure of a second protrusion reflecting light in FIG. 2H, in accordance with some embodiments;

FIG. 2K is a sectional view showing a structure of yet another light-emitting substrate, in accordance with some embodiments;

FIG. 2L is a diagram showing a structure of a slope angle of the second protrusion in FIG. 2J, in accordance with some embodiments;

FIG. 2M is a sectional view showing a structure of a light-emitting substrate of a second comparative example, in accordance with some embodiments;

FIG. 2N is a diagram showing a structure of a slope angle of a black matrix, in accordance with some embodiments;

FIG. 3 is a diagram showing a structure of a light-emitting device, in accordance with some embodiments;

FIG. 4A is a diagram showing a structure of a first light extraction layer, in accordance with some embodiments;

FIG. 4B is a diagram showing a structure of another first light extraction layer, in accordance with some embodiments;

FIG. 5 is a diagram showing a structure of a second light conversion pattern; and

FIG. 6 is a diagram showing a structure of a first/third light conversion pattern.

### DETAILED DESCRIPTION

Technical solutions in some embodiments of the present disclosure will be described clearly and completely below with reference to the accompanying drawings. However, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed in as an open and inclusive meaning, i.e., “including, but not limited to”. In the description of the specification, the terms “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or examples(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the terms “a plurality of”, “the plurality of” and “multiple” each mean two or more unless otherwise specified.

The phrase “at least one of A, B and C” has the same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

The phrase “applicable to” or “configured to” used herein means an open and inclusive expression, which does not exclude devices that are applicable to or configured to perform additional tasks or steps.

In addition, the use of the phrase “based on” is meant to be open and inclusive, since a process, step, calculation, or other action that is “based on” one or more of the stated conditions or values may, in practice, be based on additional conditions or values exceeding those stated.

Exemplary embodiments are described herein with reference to sectional views and/or plan views as idealized exemplary drawings. In the accompanying drawings, thickness of layers and sizes of regions are enlarged for clarity. Variations in shapes with respect to the drawings due to, for example, manufacturing technologies and/or tolerances may be envisaged. Therefore, the exemplary embodiments should not be construed as being limited to the shapes of the regions shown herein, but including deviations in the shapes due to, for example, manufacturing. For example, an etched region shown in a rectangular shape generally has a feature of being curved. Thus, the regions shown in the accompanying drawings are schematic in nature, and their shapes are not intended to show actual shapes of regions in a device, and are not intended to limit the scope of the exemplary embodiments.

Some embodiments of the present disclosure provide a light-emitting device. As shown in FIG. 3, the light-emitting device 300 includes a light-emitting substrate. Of course, the light-emitting device may further include other components. For example, the light-emitting device may include a circuit for providing electrical signals to the light-emitting substrate to drive the light-emitting substrate to emit light. The circuit may be referred to as a control circuit, which may include a circuit board electrically connected to the light-emitting substrate and/or an integrated circuit (IC) electrically connected to the light-emitting substrate.

In some embodiments, the light-emitting device may be a lighting device. In this case, the light-emitting device is used as a light source to realize a lighting function. For example, the light-emitting device may be a backlight module of a liquid crystal display device, a lamp for internal lighting or external lighting, a kind of signal light, or the like.

In some other embodiments, the light-emitting device may be a display device. In this case, the light-emitting substrate is a display substrate, which is used for realizing a function of displaying images (i.e., pictures). The light-emitting device may include a display or a product including the display. The display may be a flat panel display (FPD), a micro display, and the like. The display may be a transparent display or an opaque display according to whether a user can see a scene behind the display. The display may be a flexible display or a normal display (which may be referred to as a rigid display) according to whether the display can be bent or rolled. For example, the product including the display may be a computer monitor, a television, a billboard, a laser printer with a display function, a telephone, a mobile phone, a personal digital assistant (PDA), a laptop, a digital camera, a portable camcorder, a viewfinder, a vehicle, a large-area wall, a theater screen or a stadium signage, etc.

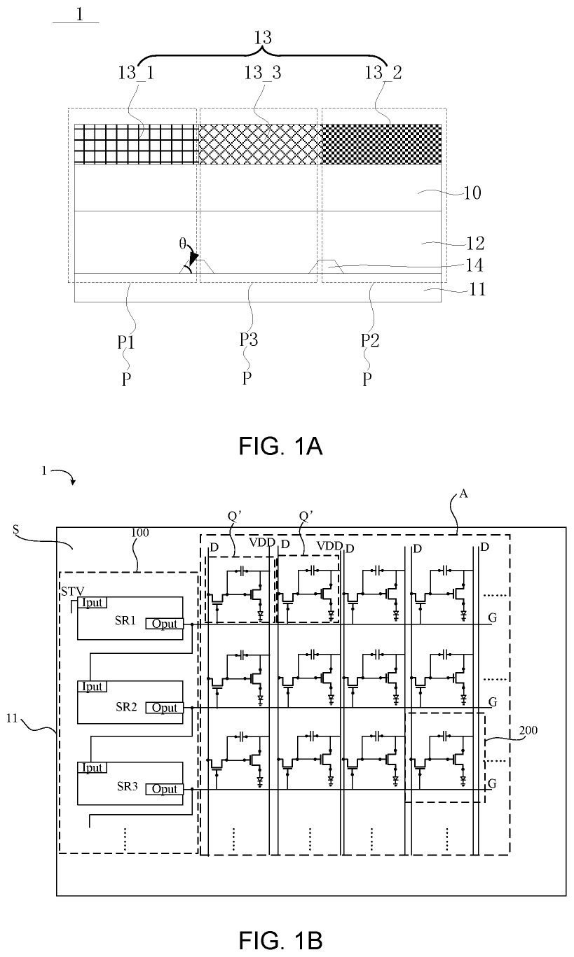

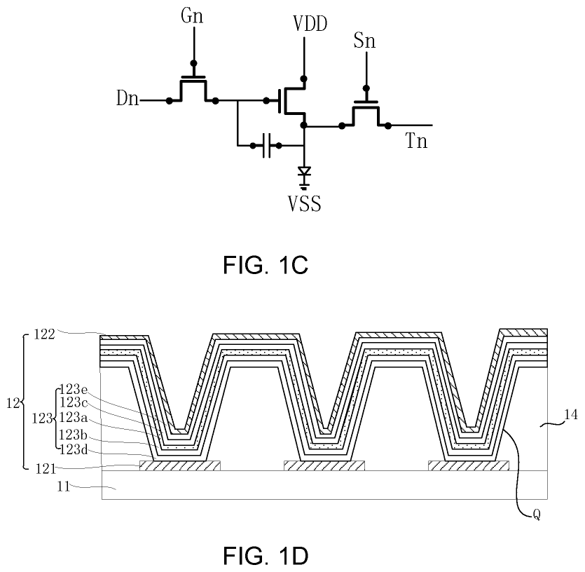

Some embodiments of the present disclosure provide a light-emitting substrate. As shown in FIG. 1A, the light-emitting substrate 1 includes a substrate 11 and a plurality of sub-pixels P disposed on the substrate 11. Each sub-pixel P includes a light-emitting element 12 disposed on the substrate 11, and a light conversion pattern 13 disposed on a light-exit side of the light-emitting element 12. The light-emitting element 12 is configured to emit light of a first color, and the light conversion pattern 13 is configured to convert a wavelength of the light emitted by the light-emitting element 12 and emit light with a converted wavelength.

For example, the light-emitting element 12 may be an electroluminescent element, such as an organic light-emitting diode (OLED) element, or a light-emitting diode. A material of the light conversion pattern 13 may include a quantum dot light-emitting material. The quantum dot light-emitting material emits light under irradiation of the light emitted by the light-emitting element 12, and the wavelength of the light emitted by the light-emitting element 12 is converted. For example, the light emitted by the light-emitting element 12 may be blue light, and the quantum dot light-emitting material may emit red light or green light under excitation of the blue light, thereby realizing the conversion of the wavelength.

In some embodiments, as shown in FIG. 1A, the plurality of sub-pixels P include at least one first sub-pixel P1, and the light conversion pattern 13 included in a respective one of the at least one first sub-pixel P1 is a first light conversion pattern 13_1. The first light conversion pattern 13_1 is configured to convert the light of the first color emitted by the light-emitting element 12 into light of a second color and emit the light of the second color.

For example, the first sub-pixel P1 may be a red sub-pixel R, and the first light conversion pattern 13_1 may include a red quantum dot light-emitting material, which emits the red light under the excitation of the blue light. Alternatively, the first sub-pixel P1 may be a green sub-pixel G, and the first light conversion pattern 13_1 may include a green quantum dot light-emitting material, which emits the green light under the excitation of the blue light.

The plurality of sub-pixels P may all be the first sub-pixels P1. Alternatively, as shown in FIG. 1A, part of the plurality of sub-pixels P may be the first sub-pixels P1.

In a case where the plurality of sub-pixels P are all the first sub-pixels P1, the light-emitting substrate 1 emits monochromatic light, such as the red light or the green light. In this case, the light-emitting substrate 1 may be used for lighting, i.e., the light-emitting substrate 1 may be used in the lighting device; alternatively, the light-emitting substrate 1 may be used to display a single-color image or picture, i.e., the light-emitting substrate 1 may be used in the display device.

In a case where the part of the plurality of sub-pixels P are the first sub-pixels P1, the remaining sub-pixels P may emit light of other colors. For example, in a case where the first sub-pixels P1 emit the red light, the remaining sub-pixels P may emit the green light, the blue light or white light. In a case where the first sub-pixels P1 emit the green light, the remaining sub-pixels P may emit the red light, the blue light or the white light. Colors of the light emitted by the remaining sub-pixels P are not limited here. As shown in FIG. 1A, the first sub-pixel P1 emits the red light, the remaining sub-pixels P in the plurality of sub-pixels P include a second sub-pixel P2 and a third sub-pixel P3, the second sub-pixel P2 emits the blue light, and the third sub-pixel P3 emits the green light. In this case, the light-emitting substrate 1 may emit light of adjustable colors (i.e., colored light). The light-emitting substrate 1 may be used for lighting or decorating, i.e., the light-emitting substrate 1 may be used in the lighting device. Alternatively, the light-emitting substrate 1 may be used to display images or pictures, i.e., the light-emitting substrate 1 may be used in the display device, such as a full-color display panel.

In some embodiments, considering an example (the full-color display panel) where the light-emitting element 12 is the electroluminescent element and the light-emitting substrate 1 is the display substrate, as shown in FIGS. 1B and 1D, the light-emitting substrate 1 has a display region A and a peripheral region S disposed on a periphery of the display region A. The display region A includes a plurality of sub-pixel regions Q′, each sub-pixel region Q′ corresponds to an opening Q, and the opening Q corresponds to a light-emitting element 12. Each sub-pixel region Q′ is provided therein with a pixel driving circuit 200 for driving a respective light-emitting element 12 to emit light. The peripheral region S is used for wiring. For example, the peripheral region S is used for arranging a gate driving circuit 100 connected to the pixel driving circuits 200.

Of course, as shown in FIG. 1C, the pixel driving circuit 200 in the light-emitting substrate 1 may have a 3T1C (3 transistors and 1 capacitor) structure as shown in FIG. 1C.

In some embodiments, as shown in FIG. 1D, the light-emitting element 12 includes a first electrode 121, a second electrode 122, and a light-emitting function layer 123 disposed between the first electrode 121 and the second electrode 122. The first electrode 121 is closer to the substrate 11 than the second electrode 122. The light-emitting function layer 123 includes a light-emitting layer 123a.

In some embodiments, the first electrode 121 may be an anode. In this case, the second electrode 122 is a cathode. In some other embodiments, the first electrode 121 may be the cathode. In this case, the second electrode 122 is the anode.

A light-emitting principle of the light-emitting element 12 is as follows. Through a circuit connected to the anode and the cathode, the anode injects holes into the light-emitting function layer 123, the cathode injects electrons into the light-emitting function layer 123, and excitons are formed in the light-emitting layer 123a by the electrons and the holes. The excitons return to a ground state through radiative transition and emit photons.

As shown in FIG. 1D, in order to improve efficiency of the electrons injected into the light-emitting layer, the light-emitting function layer 123 may further include at least one of an electronic transport layer (ETL) 123c and an electronic injection layer (EIL) 123e; and in order to improve efficiency of the holes injected into the light-emitting layer, the light-emitting function layer 123 may further include at least one of a hole transport layer (HTL) 123b and a hole injection layer (HIL) 123d. For example, the light-emitting function layer 123 may include the hole transport layer (HTL) 123b disposed between the anode and the light-emitting layer 123a, and the electronic transport layer 123c disposed between the cathode and the light-emitting layer 123a. In order to further improve efficiencies of the electrons and the holes injected into the light-emitting layer 123a, the light-emitting function layer 123 may further include the hole injection layer (HIL) 123d disposed between the anode and the hole transport layer 123b, and the electronic injection layer (EIL) 123e disposed between the cathode and the electronic transport layer 123c.

In some embodiments, as shown in FIG. 1D, the light-emitting substrate 1 may further include a pixel defining layer 14, and the pixel defining layer 14 defines a plurality of openings Q, each opening Q corresponds to a region where a sub-pixel P is located (i.e., the sub-pixel region Q′), and a plurality of light-emitting elements 12 may be arranged in a one-to-one correspondence with the plurality of openings Q. Here, the plurality of light-emitting elements 12 may be all or part of the light-emitting elements 12 included in the light-emitting substrate 1, and the plurality of openings Q may be all or part of openings Q in the pixel defining layer 14.

The light-emitting substrate 1 may be a top-emission light-emitting substrate or a bottom-emission light-emitting substrate, and the first electrode 121 may be made of a transparent material or an opaque material. In a case where the light-emitting substrate 1 is the top-emission light-emitting substrate, the first electrode 121 is made of the opaque material. In this case, if the first electrode 121 is the anode, the first electrode 121 may be made of a laminated-layer material of metal and transparent oxide, such as a laminated-layer material of silver and indium tin oxides (Ag/ITO), or a laminated-layer material of silver and indium zinc oxides (Ag/IZO). The second electrode 122 may be made of a metal material, such as magnesium, silver, aluminum or an alloy thereof (e.g., a magnesium-silver alloy, where a mass ratio of magnesium and silver may be in a range of 1:9 to 3:7), and a thickness of the metal material is relatively small, so as to achieve light transmission. Alternatively, the second electrode 122 may be made of transparent oxide, such as ITO, IZO or indium gallium zinc oxide (IGZO), so as to achieve light transmission. For example, in a case where the light-emitting element 12 emits the blue light, a transmittance of the second electrode 122 for light with the wavelength of 530 nm may be 50% to 66%, so as to achieve transmission of the blue light. If the first electrode 121 is the cathode, the first electrode 121 is made of a metal material with a low work function, such as magnesium, silver, aluminum or an alloy thereof, and the second electrode 122 is made of a transparent oxide material with a high work function, such as ITO or IZO. In a case where the light-emitting substrate 1 is the bottom-emission light-emitting substrate, the first electrode 121 is made of the transparent material. In this case, if the first electrode 121 is the anode, the first electrode 121 is made of a transparent oxide material with a high work function, such as ITO or IZO, and the second electrode 122 is made of a metal material with a low work function, such as magnesium, silver, aluminum, or an alloy thereof; if the first electrode 121 is the cathode, the first electrode 121 is made of a metal material with a low work function, and a thickness of the metal material is relatively small, so as to achieve light transmission, and the second electrode 122 is made of a laminated-layer material of metal and transparent oxide, such as a laminated-layer material of Ag and ITO (Ag/ITO) or a laminated-layer material of Ag and IZO (Ag/IZO).

Of course, in some embodiments, the light-emitting substrate 1 may be a double-sided emission light-emitting substrate. In this case, the first electrode 121 and the second electrode 122 are each made of a transparent material.

In some embodiments, as shown in FIG. 1A, in the case where the light-emitting substrate 1 is the top-emission light-emitting substrate, the light-emitting elements 12 and the light conversion patterns 13 may be located on a same side of the substrate 11. That is, the light conversion patterns 13 are located on a side of the light-emitting elements 12 away from the substrate 11. In the case where the light-emitting substrate 1 is the bottom-emission light-emitting substrate, the light-emitting elements 12 and the light conversion patterns 13 may be located on opposite sides of the substrate 11. That is, the light conversion patterns 13 are located on a side of the substrate 11 away from the light-emitting elements 12.

In some embodiments, a material of the hole injection layer 123d may be any material that can reduce a hole injection barrier and improve hole injection efficiency. For example, the material of the hole injection layer 123d is selected from any one of HATCN (Dipyrazino[2,3-f:2′, 3′-h]quinoxaline-2,3,6,7,10,11-hexacarbonitrile, also referred to as 2,3,6,7,10,11-Hexacyano-1,4,5,8,9,12-hexaazatriphenylene) and copper phthalocyanine (CuPc), or selected from hole transport materials each doped with a p-type material, such as NPB (N,N′-bis(1-naphthyl)-N,N′-diphenyl-1,1′-biphenyl-4-4′-diamine): F4TCNQ (2,3,5,6-tetrafluoro-7,7′,8,8′-tetracyanodimethyl-p-benzoquinone), TAPC (4,4′-cyclohexylidenebis[N,N-bis(p-tolyl)aniline], 4,4′-cyclohexylbis[N, N-bis(4-methylphenyl)aniline]):MnO₃. A doping ratio of the p-type material is in a range of 0.5% to 10%, inclusive. A material of the electron injection layer 123e may be any one of lithium fluoride (LiF), 8-Hydroxyquinolinolato-lithium (LiQ), ytterbium (Yb), calcium (Ca). The hole injection layer 123d and the electron injection layer 123e may be formed by evaporation.

In some embodiments, the hole transport layer 123b may be made of a material with a highest occupied molecular orbital (HOMO) energy level of −5.2 eV to −5.6 eV, inclusive, and the material has a high hole mobility. For example, the material of the hole transport layer 123b may be selected from carbazole materials, and a thickness of the hole transport layer 123b may be in a range of 100 nm to 200 nm, inclusive. The hole transport layer 123b may be formed by the evaporation. The material of the electron transport layer 123c may be selected from any one of thiophene derivatives, imidazole derivatives and azine derivatives, or a mixed material of any one of the thiophene derivatives, imidazole derivatives and azine derivatives and lithium quinolate, a doping ratio of the lithium quinolate may be in a range of 30% to 70%, inclusive. A thickness of the electron transport layer 123c may be in a range of 20 nm to 40 nm, inclusive.

In some embodiments, a material of the light-emitting layer 123a may be selected from organic light-emitting materials that emit blue light. The light-emitting layer 123a may also be formed by evaporation. A thickness of the light-emitting layer 123a may be in a range of 15 nm to 25 nm, inclusive. The light-emitting layer 123a may be formed in a whole layer by evaporation, which may reduce difficulty of the process.

In some other embodiments, the light-emitting layer 123a may include a first light-emitting sub-layer, a charge generation layer and a second light-emitting sub-layer that are sequentially stacked in a direction away from the substrate. Materials of the first light-emitting sub-layer and the second light-emitting sub-layer may each be selected from the organic light-emitting materials that emit the blue light. For example, luminescence spectrums of the first light-emitting sub-layer and the second light-emitting sub-layer are both in a range of 400 nm to 500 nm, inclusive. The charge generation layer may be made of an organic material. The charge generation layer may generate the electrons and the holes due to an action of an electric field, and the electrons and the holes respectively flow to the anode and the cathode under attraction of the electric field. As a result, it may facilitate recombination of the electrons and the holes in the first light-emitting sub-layer and the second light-emitting sub-layer for emitting light.

In some embodiments, the light-emitting element 12 may further include a hole blocking layer and an electron blocking layer. The electron blocking layer is disposed between the hole transport layer 123b and the light-emitting layer 123a, and the hole blocking layer is disposed between the electron transport layer 123c and the light-emitting layer 123a. The hole blocking layer may have a deep HOMO and a shallow lowest unoccupied molecular orbital (LUMO), which facilitates electrons transport and blocks holes transport. Similarly, the electron blocking layer may have a shallow HOMO mixed with a deep LUMO, which facilitates the holes transport and blocks the electrons transport. As a result, a recombination region of the electrons and the holes may be confined in the light-emitting layer.

In some embodiments, a material of the hole blocking layer may be selected from organic materials capable of transmitting electrons and blocking holes, and a thickness of the hole blocking layer may be in a range of 2 nm to 10 nm, inclusive. A material of the electron blocking layer may be selected from organic materials capable of transmitting holes and blocking electrons, and a thickness of the electron blocking layer may be in a range of 1 nm to 10 nm, inclusive.

In some embodiments, as shown in FIG. 1A, a thickness of the pixel defining layer 14 may be less than 3 μm. A longitudinal sectional shape of a portion of the pixel defining layer 14 corresponding to a region between every two adjacent sub-pixels P may be a trapezoid. A base angle θ of the trapezoid is less than or equal to 30 degrees. That is, a slope angle of the pixel defining layer 14 is confined to be less than or equal to 30 degrees. In this way, a level difference may be reduced in a process of evaporating organic materials, thereby improving continuity of the materials.

In some embodiments, as shown in FIG. 1A, the light-emitting substrate 1 may further include an encapsulation layer 10. In this case, there are two possible situations. In a first situation, the light-emitting elements 12 and the light conversion patterns 13 are located on the same side of the substrate 11. In this case, the encapsulation layer 10 may be located between the light-emitting elements 12 and the light conversion patterns 13. In a second situation, the light-emitting elements 12 and the light conversion patterns 13 are located on the opposite sides of the substrate 11. In this case, the encapsulation layer 10 may be disposed on the side of the light-emitting elements 12 away from the substrate 11. The encapsulation layer 10 is configured to protect the light-emitting elements 12 and prevent moisture from entering the light-emitting elements 12.

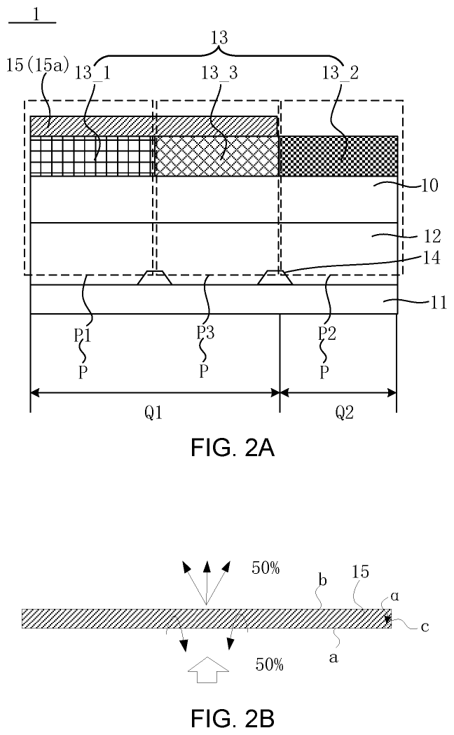

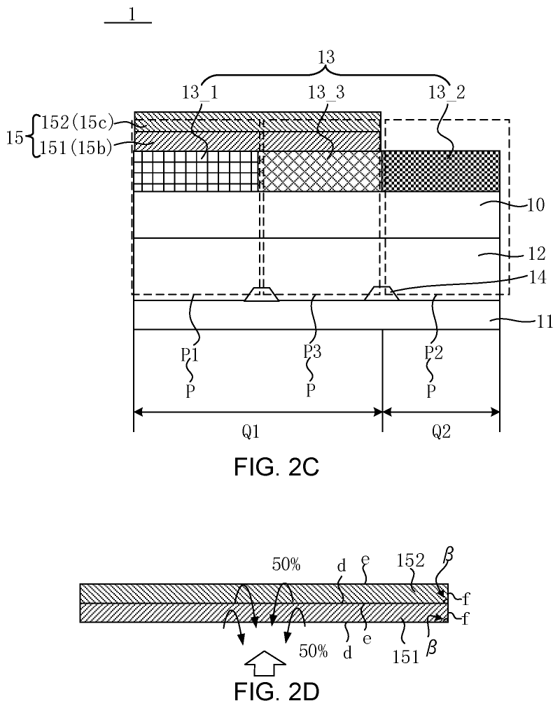

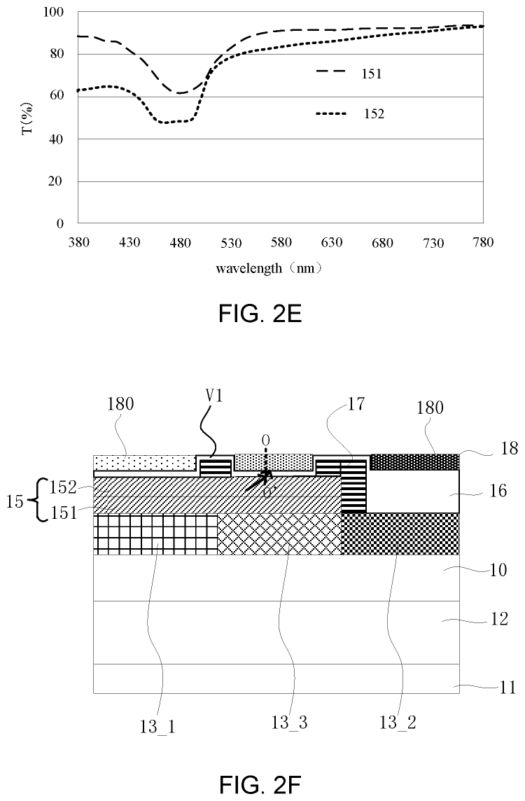

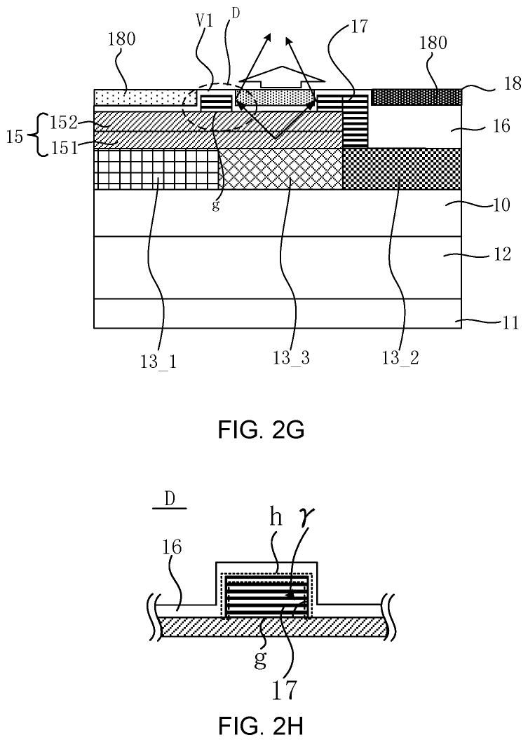

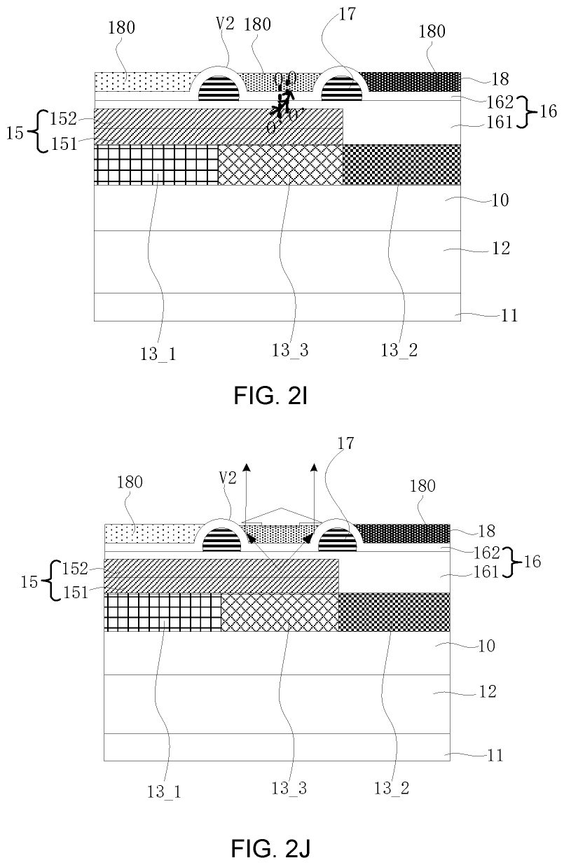

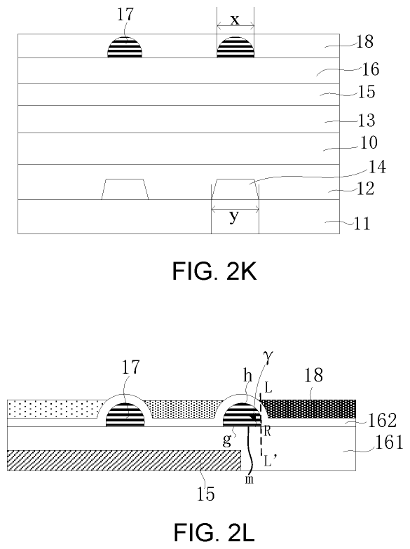

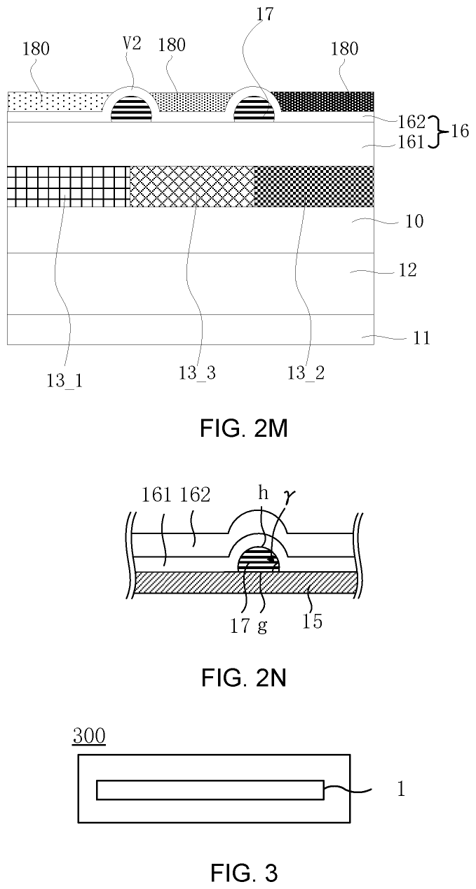

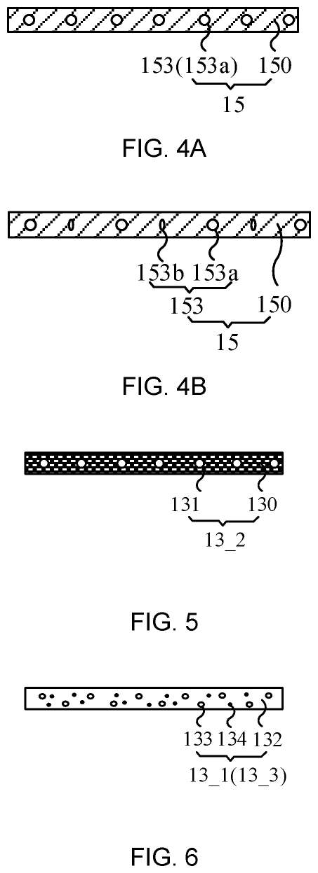

In some embodiments, as shown in FIG. 2A, the light-emitting substrate 1 further includes a first light extraction layer 15. The first light extraction layer 15 is disposed on a side of the first light conversion pattern 13_1 away from the light-emitting elements 12, and the first light extraction layer 15 is disposed at least in a region where the at least one first sub-pixel P1 is located. As shown in FIGS. 4A and 4B, the first light extraction layer 15 includes first transparent substrate(s) 150 and optically active substances 153 added in each of the first transparent substrate(s) 150. The optically active substances are selected from materials capable of selectively reflecting the light of the first color.

The first transparent substrate may be any substrate that is capable of transmitting light (which may include visible light). For example, the first transparent substrate may be a glass substrate. Alternatively, the first transparent substrate is made of a transparent polymer material, such as a polyimide (PI) material.

Here, considering an example where the light-emitting substrate 1 is the top-emission light-emitting substrate, the light-emitting elements 12, the light conversion patterns 13 and the first light extraction layer 15 are sequentially stacked in the direction away from the substrate 11. The light-emitting element 12 emits the light of the first color (e.g., the blue light), the first light conversion pattern 13_1 is configured to convert the light of the first color into the light of the second color (e.g., the red light), and the red light exits through the first light extraction layer 15.

In this process, if the first light extraction layer 15 does not include the optically active substances, in one hand, since the blue light emitted by the light-emitting element 12 itself has low efficiency, and the light-emitting element 12 has large power consumption and a short service life, an energy that can excite the quantum dot light-emitting material of the light conversion pattern for emitting light is limited; in another hand, the quantum dot light-emitting material of the light conversion pattern cannot completely absorb the blue light energy, resulting in low light conversion efficiency of the light conversion pattern and low light-exit efficiency of the light-emitting substrate, and blue light leakage to a certain extent simultaneously, which is prone to a color mixing problem.

In these embodiments, the first light extraction layer 15 is provided. The first light extraction layer 15 includes the optically active substances, and the optically active substance is selected from the materials capable of selectively reflecting the light of the first color. Therefore, the optically active substance may reflect the blue light and allow the red light or the green light to pass through. On one hand, it may prevent the light leakage. On another hand, the blue light that is reflected continues to enter the light conversion pattern 13 to excite the quantum dot light-emitting material to emit light, which may increase efficiency of the quantum dot light-emitting material absorbing the blue light. As a result, the light conversion efficiency may be improved, and color mixing and other problems may be avoided.

In some embodiments, the first transparent substrate is made of the polymeric material. In this case, as shown in FIG. 4A, the optically active substances 153 may be liquid crystal materials 153a; alternatively, as shown in FIG. 4B, the optically active substances 153 include liquid crystal materials 153a and chiral auxiliaries 153b.

In these embodiments, in a case where the optically active substances are the liquid crystal materials, the liquid crystal materials may be cholesteric liquid crystals. Since the cholesteric liquid crystal has a special helical structure, the cholesteric liquid crystal has optical properties such as optical rotation, selective reflection and circularly polarized light dichroism. In a case where the cholesteric liquid crystal has a left-helical structure, and the cholesteric liquid crystal is fixed in the polymer material in a form of a planar texture (i.e., a helical axis of the cholesteric liquid crystal is perpendicular to a plane where the first light extraction layer 15 is located), 50% of light passing through the first light extraction layer 15 is converted into circularly polarized light with a same rotation as the cholesteric liquid crystal (e.g., left-helical circularly polarized light), the circularly polarized light with the same rotation as the cholesteric liquid crystal is reflected, and circularly polarized light with an opposite rotation as the cholesteric liquid crystal (e.g., right-helical circularly polarized light) is transmitted. On contrary, in a case where the cholesteric liquid crystal has a right-helical structure, and the cholesteric liquid crystal is fixed in the polymer material in a form of a planar texture (i.e., a helical axis of the cholesteric liquid crystal is perpendicular to a plane where the first light extraction layer 15 is located), right-helical circularly polarized light is reflected, and left-helical circularly polarized light is transmitted. In a case where the cholesteric liquid crystals include both the cholesteric liquid crystals having the left-helical structure and the cholesteric liquid crystals having the right-helical structure, 50% of the light passing through the first light extraction layer 15 is converted into circularly polarized light with the same rotation as the cholesteric liquid crystal having the left-helical structure (e.g., the left-helical circularly polarized light), and the circularly polarized light with the same rotation as the cholesteric liquid crystal having the left-helical structure is reflected; another 50% of the light is converted into circularly polarized light with the opposite rotation as the cholesteric liquid crystal having the right-helical structure (e.g., the right-helical circularly polarized light), and the circularly polarized light with the opposite rotation as the cholesteric liquid crystal having the right-helical structure is reflected. As a result, 100% of the light is totally reflected.

In practical applications, the liquid crystal materials, polymer monomers and initiators may be mixed, and the polymer monomers may be initiated to perform polymerization under heating or lighting, so that the liquid crystal materials may be fixed in the polymer materials in the form of the planar texture.

In a case where the optically active substances include the liquid crystal materials and the chiral auxiliaries, the liquid crystal materials may be nematic liquid crystals. In this case, the chiral auxiliaries may be added to the nematic liquid crystals. A director of the nematic liquid crystals is adjusted by the chiral auxiliaries, so that the nematic liquid crystals may generate obvious helical structures. As a result, the cholesteric liquid crystals are obtained. A fabricating method may be referred to the above examples in which the optically active substances are the liquid crystal materials, and details will not be described here.

In some embodiments, the first light extraction layer 15 has a single-layer structure. In this case, as shown in FIG. 2B, considering an example where the optically active substances are the cholesteric liquid crystals having the left-helical structures, 50% of the light passing through the first light extraction layer 15 is converted into the circularly polarized light with the same rotation as the cholesteric liquid crystals (e.g., the left-helical circularly polarized light), the circularly polarized light with the same rotation as the cholesteric liquid crystals is reflected, and the circularly polarized light with the opposite rotation as the cholesteric liquid crystals (e.g., the right-helical circularly polarized light) is transmitted. As a result, 50% of the blue light may be reflected, which may improve the light conversion efficiency and reduce the blue light leakage. Of course, the optically active substances may include the cholesteric liquid crystals with the left-helical structures and the cholesteric liquid crystals with the right-helical structures. In this case, as mentioned above, 100% of the blue light may be reflected, which may further improve the light conversion efficiency and reduce the blue light leakage.

In some other embodiments, as shown in FIG. 2C, the first light extraction layer 15 includes a first sub-layer 151 and a second sub-layer 152 that are sequentially stacked in a direction away from the light-emitting elements 12. Chirality of optically active substances included in the first sub-layer 151 is opposite to chirality of optically active substances included in the second sub-layer 152.

That is, in these embodiments, the optically active substances included in the first sub-layer 151 may also be liquid crystal materials, or include liquid crystal materials and chiral auxiliaries; and the optically active substances included in the second sub-layer 152 may also be liquid crystal materials, or include liquid crystal materials and chiral auxiliaries.

The first sub-layer 151 and the second sub-layer 152 are provided. In a case where the first sub-layer 151 reflects 50% of the light (e.g., the left-helical circularly polarized light), as shown in FIG. 2D, since the chirality of the optically active substances included in the second sub-layer 152 is opposite to the chirality of the optically active substances included in the first sub-layer 151, another 50% of the light (i.e., the right-helical circularly polarized light passing through the first sub-layer 151) will be reflected back by the second sub-layer 152. As a result, 100% of the light may be reflected, so that the blue light may be utilized to the maximum extent, thereby improving the light conversion efficiency.

In some embodiments, in a case where the first light extraction layer 15 includes the first sub-layer 151 and the second sub-layer 152, and the optically active substances included in the first sub-layer 151 and the optically active substances included in the second sub-layer 152 are each liquid crystal materials, a first transparent substrate included in the first sub-layer 151 and another first transparent substrate included in the second sub-layer 152 are made of a same material or different materials.

In these embodiments, the first transparent substrate included in the first sub-layer 151 and the first transparent substrate included in the second sub-layer 152 may be made of a same polymer material, or made of different polymer materials that are capable of transmitting light.

In some other embodiments, in a case where the first light extraction layer 15 includes the first sub-layer 151 and the second sub-layer 152, and the optically active substances included in the first sub-layer 151 and the optically active substances included in the second sub-layer 152 each include liquid crystal materials and chiral auxiliaries, a first transparent substrate included in the first sub-layer 151 and another first transparent substrate included in the second sub-layer are made of a same material or different materials, and liquid crystal materials included in the first sub-layer 151 and liquid crystal materials included in the second sub-layer 152 are the same or different.

In these embodiments, the first transparent substrate included in the first sub-layer 151 and the first transparent substrate included in the second sub-layer 152 may be made of a same polymer material, or made of different polymer materials that are capable of transmitting light. The liquid crystal materials included in the first sub-layer 151 and the liquid crystal materials included in the second sub-layer 152 may also be same nematic liquid crystal materials. In this case, by adding different chiral auxiliaries, the purpose of making the chirality of the optically active substances included in the first sub-layer 151 and the chirality of the optically active substances included in the second sub-layer 152 opposite may be achieved.

An addition ratio of the chiral auxiliaries is not limited, as long as the chiral auxiliaries can change the nematic liquid crystals into desired helical structures.

In some embodiments, a doping ratio of the chiral auxiliaries is less than 20 wt %. The doping ratio of the chiral auxiliaries refers to a mass proportion of the chiral auxiliaries in reaction raw materials of the polymer. In an example where the first light extraction layer 15 has the single-layer structure, and the reaction raw materials of the first light extraction layer 15 include the liquid crystal materials, the polymer monomers, the initiators and the chiral auxiliaries, the doping ratio of the chiral auxiliaries is equal to a ratio of a mass of the chiral auxiliaries to a total mass of the reaction raw materials. A doping ratio of the chiral auxiliaries in the first sub-layer and a doping ratio of the chiral auxiliaries in the second sub-layer may be referred to the above descriptions, and details will not be repeated here.

In these embodiments, the doping ratio of the chiral auxiliaries is controlled to avoid excessive addition of the chiral auxiliaries, which may lead to phase separation during polymerization, resulting in reducing the transmittance and increasing the haze.

Optionally, the doping ratio of the chiral auxiliaries is less than 10 wt %.

In some embodiments, as shown in FIGS. 2A and 2C, the plurality of sub-pixels P further include at least one second sub-pixel P2, and the light conversion pattern 13 included in a respective one of the at least one second sub-pixel P2 is a second light conversion pattern 13_2. As shown in FIG. 5, the second light conversion pattern 13_2 includes a second transparent substrate 130 and scattering particles 131 added in the second transparent substrate 130.

That is, the second light conversion pattern 13_2 is different from the first light conversion pattern 13_1. The second light conversion pattern 13_2 only scatters the light of the first color by the scattering particles, so as to increase the light-exit efficiency of the light of the first color. In this case, the second sub-pixel P2 may be the blue sub-pixel B.

In this case, there are two possible situations depending on whether the first light extraction layer 15 has the single-layer structure or the first light extraction layer 15 includes the first sub-layer 151 and the second sub-layer 152.

In a first situation, as shown in FIG. 2A, the first light extraction layer 15 has the single-layer structure. In this case, the first light extraction layer 15 has a first pattern 15a, a first region Q1 is located within an orthographic projection of the first pattern 15a on the substrate 11, and the orthographic projection of the first pattern 15a on the substrate 11 is located outside a second region Q2. The first region is a region where other sub-pixels P in the plurality of sub-pixels P except the at least one second sub-pixel P2 are located, and the second region is a region where the at least one second sub-pixel P2 is located. In this case, on one hand, the first light extraction layer 15 does not cover the region where the at least one second sub-pixel P2 is located, and does not reflect light emitted by light-emitting element 12 located in a region where the blue sub-pixel B is located, so that the light-exit efficiency of the blue light may increase. On another hand, the first light extraction layer 15 may be arranged in the region where all the other sub-pixels P except the at least one second sub-pixel P2 are located. In this case, considering an example where the plurality of sub-pixels P include the red sub-pixel(s) R, the green sub-pixel(s) G and the blue sub-pixel(s) B, as shown in FIG. 2A, the first light extraction layer 15 may be disposed in a region where the red sub-pixel(s) R and the green sub-pixel(s) G are located. In this way, light emitted by light-emitting elements 12 located in the region where the red sub-pixel(s) R and the green sub-pixel(s) G are located may be reflected by the first light extraction layer 15 (as described above, in a case where the first light extraction layer 15 includes the cholesteric liquid crystals having the left-helical structures or the right-helical structures, 50% of the blue light may be reflected in theory), so that light conversion patterns 13 corresponding to the red sub-pixel(s) R and the green sub-pixel(s) G continue to absorb the blue light and convert the wavelength of the blue light. Therefore, it may improve the light conversion efficiency of the red light and the green light, and reduce the blue light leakage in the region where the red sub-pixel(s) R and the green sub-pixel(s) G are located, thereby reducing the color mixing.

In a second situation, as shown in FIG. 2C, the first light extraction layer 15 includes the first sub-layer 151 and the second sub-layer 152. In this case, the first sub-layer 151 has a second pattern 15b, and the second sub-layer 152 has a third pattern 15c. A first region Q1 is located within an orthographic projection of at least one of the second pattern 15b and the third pattern 15c on the substrate 11, and orthographic projections of the second pattern and the third pattern on the substrate 11 are located outside a second region Q2. The first region is a region where other sub-pixels P in the plurality of sub-pixels P except the at least one second sub-pixel P2 are located, and the second region is a region where the at least one second sub-pixel P2 is located.

In this case, on one hand, the first sub-layer 151 and the second sub-layer 152 each do not cover the region where at least one second sub-pixel P2 is located, and do not reflect light emitted by light-emitting element 12 located in a region where the blue sub-pixel B is located, so that the light-exit efficiency of the blue light may increase. On another hand, at least one of the first sub-layer 151 and the second sub-layer 152 may be arranged in the region where all the other sub-pixels P except the at least one second sub-pixel P2 are located. In this case, according to whether the second pattern is completely overlapped with the third pattern, there are many possible cases. In a first case, as shown in FIG. 2C, an orthographic projection of the second pattern on the substrate 11 is completely overlapped with an orthographic projection of the third pattern on the substrate 11. In this case, the first sub-layer 151 and the second sub-layer 152 may both be arranged in the region where all the other sub-pixels P in the plurality of sub-pixels P except the at least one second sub-pixel P2 are located. In this way, light emitted by light-emitting elements included in all the other sub-pixels P in the plurality of sub-pixels P except the at least one second sub-pixel P2 may be reflected by the first light extraction layer 15 (as described above, in a case where the helical structures of the cholesteric liquid crystals included in the first sub-layer 151 and the helical structures of the cholesteric liquid crystals included in the second sub-layer 152 are opposite, 100% of the blue light may be reflected in theory), so that light conversion patterns 13 included in all the other sub-pixels P in the plurality of sub-pixels P except the at least one second sub-pixel P2 continue to absorb the blue light and convert the wavelength of the blue light. Therefore, it may improve the light conversion efficiency of light of other colors except the blue light, and reduce the blue light leakage, thereby reducing the color mixing. In a second case, the orthographic projection of the second pattern on the substrate 11 is not completely overlapped with the orthographic projection of the third pattern on the substrate 11. In this case, an overlapping portion of the orthographic projections of the first sub-layer 151 and the second sub-layer 152 may be located in a region where a first part of sub-pixels in the plurality of sub-pixels P except the at least one second sub-pixel P2 are located. The light conversion efficiency and the blue light reflection condition of the first part of sub-pixels may be referred to the descriptions of the first case in which the first sub-layer 151 and the second sub-layer 152 both reflect the blue light, and details will not be described here. A portion of the first sub-layer 151 that is not overlapped with the orthographic projection of the second sub-layer 152 may be located in a region where a second part of sub-pixels in the plurality of sub-pixels P except the at least one second sub-pixel P2 are located, and a portion of the second sub-layer 152 that is not overlapped with the orthographic projection of the first sub-layer 151 may be located in a region where a third part of sub-pixels in the plurality of sub-pixels P except the at least one second sub-pixel P2 are located. The light conversion efficiency and the blue light reflection condition of the second part of sub-pixels, and the light conversion efficiency and the blue light reflection of the third part of sub-pixels may be referred to the descriptions of the first situation in which the first light extraction layer 15 reflects the blue light, and details will not be described here.

In some embodiments, as shown in FIG. 2C, in the case where the first light extraction layer 15 includes the first sub-layer 151 and the second sub-layer 152, the orthographic projection of the first sub-layer 151 on the substrate 11 is located within the orthographic projection of the second sub-layer 152 on the substrate 11.

That is, a coverage area of the orthographic projection of the second sub-layer 152 on the substrate 11 is greater than or equal to a coverage area of the orthographic projection of the first sub-layer 151 on the substrate 11. In these embodiments, 50% of the circularly polarized light passing through the first sub-layer 151 continues to be reflected when passing the second sub-layer 152, which may realize 100% reflection of the blue light. In addition, in a case where the coverage area of the orthographic projection of the second sub-layer 152 on the substrate 11 is greater than the coverage area of the orthographic projection of the first sub-layer 151 on the substrate 11, it may be possible to prevent the blue light from leaking at edges of the first sub-layer 151.

In some embodiments, in the case where the first light extraction layer 15 includes the first sub-layer 151 and the second sub-layer 152, a thickness of the first sub-layer 151 is in a range of 1 μm to 10 μm, inclusive, and a thickness of the second sub-layer 152 is in a range of 1 μm to 10 μm, inclusive.

Under a condition of a constant helical pitch, the number of periodic structures (i.e., the number of helices) in planar textures of cholesteric liquid crystals in the first sub-layer 151 and the second sub-layer 152 are related to thicknesses of the first sub-layer 151 and the second sub-layer 152. By adjusting the thicknesses of the first sub-layer 151 and the second sub-layer 152, the reflectance may be adjusted, thereby improving the light conversion efficiency.

In some embodiments, considering an example where the light emitted by the light-emitting element 12 is the blue light, in the case where the first light extraction layer 15 has the single-layer structure, a light transmittance of the first light extraction layer 15 for light with the wavelength in a range of 400 nm to 500 nm inclusive is in a range of 40% to 70% inclusive; and the light transmittance of the first light extraction layer 15 for light with the wavelength more than 500 nm is more than 90%.

That is, 40% to 70% of the blue light may pass through the first light extraction layer 15, which means that the first light extraction layer 15 may reflect about 50% of the blue light. More than 90% of light of other colors except the blue light is allowed to pass through the first light extraction layer 15, so that it may be possible to ensure a relatively high transmittance of the red light and the green light, and thus increase color purity and brightness of both the red light and the green light while reducing the blue light leakage to some extent.

In some other embodiments, considering an example where the light emitted by the light-emitting element 12 is the blue light, in the case where the first light extraction layer 15 includes the first sub-layer 151 and the second sub-layer 152, light transmittances of both the first sub-layer 151 and the second sub-layer 152 for the light with the wavelength in the range of 400 nm to 500 nm inclusive is in a range of 40% to 70%, inclusive, and the light transmittances of both the first sub-layer 151 and the second sub-layer 152 for the light with the wavelength more than 500 nm is more than 90%.

That is, the first sub-layer 151 and the second sub-layer 152 each may reflect about 50% of the blue light, which may increase blue light reflectance to a greatest extent and improve the light conversion efficiency. In addition, More than 90% of the light of other colors except the blue light is allowed to pass through both the first sub-layer 151 and the second sub-layer 152, so that it may also be possible to ensure a relatively high transmittance of the red light and the green light, and thus increase the color purity and brightness of both the red light and the green light while reducing the blue light leakage to a greatest extent.

In some embodiments, the light transmittance of at least one of the first sub-layer 151 and the second sub-layer 152 for the light with the wavelength in the range of 400 nm to 500 nm inclusive is greater than or equal to 50%.

In these embodiments, in order to prevent a large amount of the blue light from being absorbed instead of being reflected when the blue light passes the first sub-layer 151 and the second sub-layer 152, the transmittances of both the first sub-layer 151 and the second sub-layer 152 are limited to be greater than or equal to 50%, so that there may be sufficient blue light to be reflected. As a result, the blue light may be effectively utilized, and the light conversion efficiency may be improved.

In some embodiments, a difference between a center wavelength of the light transmitted by the first sub-layer 151 and a center wavelength of the light transmitted by the second sub-layer 152 is less than or equal to 20 nm.

A center wavelength of a laser beam emitted by a laser device is a wavelength corresponding to a center position of full width at half maximum (FWHM) of a spectrum measured under rated power at a certain temperature. The full width at half maximum refers to a wavelength difference corresponding to intensities when the intensities on two sides of the spectrum peak drop to half of the peak value.

Here, the center wavelength refers to a wavelength corresponding to a center position of full width at half maximum of a transmission spectrum, and the difference is that the full width at half maximum refers to a wavelength difference corresponding to intensities when the intensities on two sides of a valley of the transmission spectrum rise to half of the valley value. As shown in FIG. 2E, it is a comparison diagram of the transmission spectra of the first sub-layer 151 and the second sub-layer 152.

In these embodiments, the difference between the center wavelength of the light transmitted by the first sub-layer 151 and the center wavelength of the light transmitted by the second sub-layer 152 is confined to the above range, which may reduce the blue light leakage to a greatest extent.

The reason is as follows. Considering an example where a peak value of the light emitted by the light-emitting element 12 is 460 nm and a half-peak width thereof is 20 nm, the center wavelength of the light transmitted by the first sub-layer 151 and the center wavelength of the light transmitted by the second sub-layer 152 are each in a range of 450 nm to 470 nm, inclusive. As the light transmitted by the first sub-layer 151 and the light transmitted by the second sub-layer 152 each deviate from the center wavelength, the transmittance will increase and the reflectance will decrease. In a case where the deviation is too large, both the reflectance and the transmittance will not reach an expectation, so that the reflectance of the light extraction layer 15 for the blue light and the transmittance of the light extraction layer 15 for red light and green light both decrease.

In some embodiments, in the case where the first light extraction layer 15 has the single-layer structure, a refractive index of the first light extraction layer 15 is greater than or equal to a refractive index of the light conversion patterns 13 in a region where the first light extraction layer 15 is located.

In this way, it may be possible to prevent total reflection of light at a boundary between the light conversion patterns 13 and the first light extraction layer 15, and thus the light extraction efficiency may be improved.

In some other embodiments, in the case where the first light extraction layer 15 includes the first sub-layer 151 and the second sub-layer 152, refractive indices of the first sub-layer 151 and the second sub-layer 152 are each greater than or equal to the refractive index of light conversion patterns 13 in a region where the first sub-layer 151 and the second sub-layer 152 are located.

In this way, it may be possible to prevent total reflection of light at a boundary between the light conversion pattern 13 and the first sub-layer 151 or a boundary between the light conversion pattern 13 and the second sub-layer 152, and thus the light extraction efficiency may be improved.

In some embodiments, as shown in FIGS. 2A and 2B, in the case where the first light extraction layer 15 has the single-layer structure, the first light extraction layer 15 has a first surface a proximate to the substrate 11, a second surface b away from the substrate 11, and third surfaces c each connected to the first surface a and the second surface b. An included angle α between the third surface c and the first surface a is greater than or equal to 30 degrees and less than or equal to 150 degrees.

In these embodiments, a slope angle of the first light extraction layer 15 is confined to be in the above range, so that blue light at different incident angles may be reflected to a greatest extent. As a result, it may improve the reflectance of the first light extraction layer 15 to a greatest extent, and reduce the light leakage at an edge of the first light extraction layer 15.

In some embodiments, as shown in FIGS. 2C and 2D, in the case where the first light extraction layer 15 includes the first sub-layer 151 and the second sub-layer 152, the first sub-layer 151 and the second sub-layer 152 each include a fourth surface d proximate to the substrate 11, a fifth surface e away from the substrate 11, and a sixth surface f connected to the fourth surface d and the fifth surface e. An included angle β between the sixth surface f and the fourth surface d of the first sub-layer 151 and an included angle β between the sixth surface f and the fourth surface d of the second sub-layer 152 are each greater than or equal to 30 degrees and less than or equal to 150 degrees.

In these embodiments, a slope angle of the first sub-layer 151 is greater than or equal to 30 degrees and less than or equal to 150 degrees, and a slope angle of the second sub-layer 152 is greater than or equal to 30 degrees and less than or equal to 150 degrees. In this way, the blue light at different incident angles may also be reflected to a greatest extent, thereby reducing light leakage at edges of the first sub-layer 151 and the second sub-layer 152.

Slope angles of the first sub-layer 151 and the second sub-layer 152 may be the same or different. The orthographic projection of the first sub-layer 151 on the substrate 11 may be completely overlapped with the orthographic projection of the second sub-layer 152 on the substrate 11 (which includes that, the orthographic projection of the first sub-layer 151 on the substrate 11 is within the orthographic projection of the second sub-layer 152 on the substrate 11, and there is a gap or no gap between the two orthographic projections; or the orthographic projection of the second sub-layer 152 on the substrate 11 is within the orthographic projection of the first sub-layer 151 on the substrate 11, and there is a gap or no gap between the two orthographic projections). Alternatively, the orthographic projection of the first sub-layer 151 may not be completely overlapped with the orthographic projection of the second sub-layer 152.

In a case where the slope angles of the first sub-layer 151 and the second sub-layer 152 are the same (for example, the slope angles are both 30 degrees), an area of the orthographic projection of the first sub-layer 151 on the substrate 11 is equal to an area of the fourth surface of the first sub-layer 151, and an area of the orthographic projection of the second sub-layer 152 on the substrate 11 is equal to an area of the fourth surface d of the second sub-layer 152. In this case, the orthographic projection of the first sub-layer 151 on the substrate 11 is within the orthographic projection of the second sub-layer 152 on the substrate 11, and the gap exists between the two orthographic projections; alternatively, the orthographic projection of the second sub-layer 152 on the substrate 11 is within the orthographic projection of the first sub-layer 151 on the substrate 11, and the gap exists between the two orthographic projections; alternatively, the orthographic projection of the first sub-layer 151 on the substrate 11 is not completely overlapped with the orthographic projection of the second sub-layer 152 on the substrate 11. In a case where the slope angles of the first sub-layer 151 and the second sub-layer 152 are different (for example, the slope angle of the first sub-layer 151 is 30 degrees and the slope angle of the second sub-layer 152 is 150 degrees), the area of the orthographic projection of the first sub-layer 151 on the substrate 11 is equal to the area of the fourth surface of the first sub-layer 151, and the area of the orthographic projection of the second sub-layer 152 on the substrate 11 is equal to an area of the fifth surface of the second sub-layer 152. In this case, the orthographic projection of the first sub-layer 151 on the substrate 11 is within the orthographic projection of the second sub-layer 152 on the substrate 11, and there is the gap or no gap between the two orthographic projections; alternatively, the orthographic projection of the second sub-layer 152 on the substrate 11 is within the orthographic projection of the first sub-layer 151 on the substrate 11, and there is the gap or no gap between the two orthographic projections; alternatively, the orthographic projection of the first sub-layer 151 on the substrate 11 is not completely overlapped with the orthographic projection of the second sub-layer 152 on the substrate 11.

In some embodiments, as shown in FIG. 2F, the light-emitting substrate 1 further includes a second light extraction layer 16. The second light extraction layer 16 is disposed on a side of the first light extraction layer 15 away from the light-emitting elements 12. A refractive index of the second light extraction layer 16 is smaller than the refractive index of the first light extraction layer 15, so as to change an exit angle of the light exiting from the first light extraction layer 15.

The refractive index of the second light extraction layer 16 is less than the refractive index of the first light extraction layer 15, which means that, in the case where the first light extraction layer 15 has the single-layer structure, the refractive index of the second light extraction layer 16 is less than the refractive index of the first light extraction layer 15; and in the case where the first light extraction layer 15 includes the first sub-layer 151 and the second sub-layer 152, the refractive index of the second light extraction layer 16 is less than the refractive index of the second sub-layer 152. In these embodiments, the refractive index of the second light extraction layer 16 is set to be less than the refractive index of the first light extraction layer 15, so that the exit angle of the light exiting from the first light extraction layer 15 is changed. In this way, as shown in FIG. 2F, the light exiting from the first light extraction layer 15 is refracted in a direction proximate to a normal line (OO′), so that light may be converged, which may improve brightness in a front viewing direction.

In some embodiments, as shown in FIGS. 2F and 2G, the second light extraction layer 16 has a single-layer structure. Alternatively, as shown in FIGS. 21 and 2J, the second light extraction layer 16 includes a third sub-layer 161 and a fourth sub-layer 162 that are sequentially arranged in the direction away from the substrate 11. A refractive index of the third sub-layer 161 is less than the refractive index of the first light extraction layer 15, and a refractive index of the fourth sub-layer 162 is less than the refractive index of the third sub-layer 161.

In these embodiments, in a case where the second light extraction layer 16 has the single-layer structure, the light exiting from the first light extraction layer 15 may be refracted once by the second light extraction layer 16, thereby improving the brightness in the front viewing direction. In a case where the second light extraction layer 16 includes the third sub-layer 161 and the fourth sub-layer 162, the light exiting from the first light extraction layer 15 may be refracted for a first time by the third sub-layer 161 of the second light extraction layer 16 firstly, so as to converge the light for a first time; and then light exiting from the third sub-layer 161 may be refracted for a second time by the fourth sub-layer 162 of the second light extraction layer 16, so as to converge the light for a second time. As a result, the brightness in the front viewing direction may be further improved. In addition, reducing the refractive index twice may avoid the light being totally reflected at a boundary between the first light extraction layer 15 and the second light extraction layer 16 caused by an excessive difference between the refractive index of the first light extraction layer 15 and the refractive index of the second light extraction layer 16.

Of course, the second light extraction layer 16 may have a multi-layer structure (e.g., a structure having three or more layers), which may also have an effect of converging the light exiting from the first light extraction layer 15 for multiple times. The number of sub-layers included in the second light extraction layer 16 is not limited here, and the above descriptions are only illustrative. In practical applications, the number of the sub-layers included in the second light extraction layer 16 may be set according to actual situations, and all examples in which light is converged for multiple times through multiple refractions are within the scope of the present disclosure.

In some embodiments, as shown in FIGS. 2F and 2G, in the case where the second light extraction layer 16 has the single-layer structure, the second light extraction layer 16 is provided with a first protrusion V1 thereon corresponding to a region between every two adjacent sub-pixels P. The first protrusion V1 is configured to change the exit angle of the light exiting from the first light extraction layer 15. As shown in FIGS. 21 and 2J, in the case where the second light extraction layer 16 includes the third sub-layer 161 and the fourth sub-layer 162, at least one of the third sub-layer 161 and the fourth sub-layer 162 is provided with a second protrusion V2 thereon corresponding to the region between every two adjacent sub-pixels P. The second protrusion V2 is configured to change the exit angle of the light exiting from the first light extraction layer 15.

In these embodiments, in the case where the second light extraction layer 16 has the single-layer structure, the first protrusion V1 is provided on the second light extraction layer 16 corresponding to the region between every two adjacent sub-pixels P, and the protrusion structure is used to change a normal direction of reflection. As a result, the light exiting from the first light extraction layer 15 may be reflected to two sides of the protrusion structure, and the light may also be converged, so as to improve the brightness in the front viewing direction.

In the case where the second light extraction layer 16 includes the third sub-layer 161 and the fourth sub-layer 162, as shown in FIG. 2I, the second protrusion V2 is provided on the at least one of the third sub-layer 161 and the fourth sub-layer 162 corresponding to the region between every two adjacent sub-pixels P. Similarly to the first protrusion V1, the second protrusion V2 may also converge the light, so as to improve the brightness in the front viewing direction.

Here, it will be noted that, in the case where the second light extraction layer 16 includes the third sub-layer 161 and the fourth sub-layer 162, only a case that the second protrusion V2 is provided on the fourth sub-layer 162 corresponding to the region between every two adjacent sub-pixels P is disclosed in FIGS. 21 and 2J. Those skilled in the art could understand that the second protrusion V2 may also be provided on the third sub-layer 161 corresponding to the region between every two adjacent sub-pixels P, which may also serve a similar function.

In addition, FIGS. 21 and 2J only show a case that the second light extraction layer 16 includes the third sub-layer 161 and the fourth sub-layer 162, and the second protrusion V2 is provided on the fourth sub-layer 162 corresponding to the region between every two adjacent sub-pixels P. In this case, the third sub-layer 161 may play a planarization function.

In some embodiments, a thickness of the third sub-layer 161 is greater than 3.5 μm. A thickness of the fourth sub-layer 162 is less than 2.5 μm.

In these embodiments, the third sub-layer 161 may play the planarization function on a premise of ensuring the brightness in the front viewing direction.

In some embodiments, a difference between the refractive index of the third sub-layer 161 and the refractive index of the fourth sub-layer 162 is greater than 0.2. In this way, the light exiting from the first light extraction layer 15 may be refracted in the direction proximate to the normal line (OO′) to a greatest extent, so that the light convergence may be enhanced and the brightness in the front viewing direction may be further improved.

In some embodiments, as shown in FIGS. 2F to 2J, the light-emitting substrate 1 further includes a black matrix 17. In the case where the second light extraction layer 16 has the single-layer structure, the black matrix 17 is disposed between the first light extraction layer 15 and the second light extraction layer 16, so that the first protrusion V1 is provided on the second light extraction layer 16 corresponding to the region between every two adjacent sub-pixels. In the case where the second light extraction layer 16 includes the third sub-layer 161 and the fourth sub-layer 162, the black matrix 17 is disposed between the third sub-layer 161 and the first light extraction layer 15, so that the second protrusion V2 is provided on the third sub-layer 161 corresponding to the region between every two adjacent sub-pixels P; alternatively, the black matrix 17 is disposed between the third sub-layer 161 and the fourth sub-layer 162, so that the second protrusion V2 is provided on the fourth sub-layer 162 corresponding to the region between every two adjacent sub-pixels P.

In these embodiments, FIGS. 2F and 2G show a case where the second light extraction layer 16 has the single-layer structure, and the black matrix 17 is disposed between the first light extraction layer 15 and the second light extraction layer 16. FIGS. 21 and 2J show a case where the black matrix 17 is disposed between the third sub-layer 161 and the fourth sub-layer 162. Those skilled in the art could understand that the black matrix 17 may be disposed between the third sub-layer 161 and the first light extraction layer 15.

In these embodiments, the black matrix 17 may be used to absorb external light using the light absorption property thereof, thereby avoiding a defect that the light-emitting substrate reflects the external light, which is not conducive to display effect. In addition, the black matrix 17 can also improve a contrast ratio and prevent the color crosstalk.

In some embodiments, for light with the wavelength in a range of 380 nm to 780 nm, inclusive, absorbance per micron of the black matrix 17 is greater than 0.5/μm, which may improve a light absorption effect.

In some embodiments, as shown in FIG. 2K, an orthographic projection of the black matrix 17 on the substrate 11 is within an orthographic projection of the pixel defining layer 14 on the substrate 11, and a space exists between an orthographic projection of a border of the black matrix 17 on the substrate 11 and an orthographic projection of a border of the pixel defining layer 14 on the substrate 11.

That is, an area occupied by the black matrix 17 is smaller than an area occupied by the pixel defining layer 14. As shown in FIG. 2K, x is smaller than y, which may increase an aperture ratio.

In some embodiments, as shown in FIG. 2H, in the case where the second light extraction layer 16 has the single-layer structure, a portion of the black matrix 17 located between every two adjacent sub-pixels P includes a seventh surface g in contact with the first light extraction layer 15 and an eighth surface h in contact with the second light extraction layer 16. In the case where the second light extraction layer 16 includes the third sub-layer 161 and the fourth sub-layer 162, and the black matrix 17 is located between the third sub-layer 161 and the first light extraction layer 15, as shown in FIG. 2N, a portion of the black matrix 17 located between every two adjacent sub-pixels P includes a seventh surface g in contact with the first light extraction layer 15 and an eighth surface h in contact with the third sub-layer 161. In the case where the second light extraction layer 16 includes the third sub-layer 161 and the fourth sub-layer 162, and the black matrix 17 is located between the third sub-layer 161 and the fourth sub-layer 162, as shown in FIG. 2L, a portion of the black matrix 17 located between every two adjacent sub-pixels P includes a seventh surface g in contact with the third sub-layer and an eighth surface h in contact with the fourth sub-layer 162. For the black matrix 17 located between the first light extraction layer 15 and the second light extraction layer 16, an included angle γ between the seventh surface g and the eighth surface h is greater than 30 degrees. For the black matrix 17 located between the first light extraction layer 15 and the third sub-layer 161, an included angle γ between the seventh surface g and the eighth surface h is greater than 30 degrees. For the black matrix 17 located between the third sub-layer 161 and the fourth sub-layer 162, an included angle γ between the seventh surface g and the eighth surface h is greater than 30 degrees.

In these embodiments, by confining a slope angle of the black matrix 17, it may be possible to confine a slope angle of the second protrusion V2, thereby further increasing the brightness in the front viewing direction.

In some embodiments, for the black matrix 17 located between the first light extraction layer 15 and the second light extraction layer 16, the black matrix 17 located between the first light extraction layer 15 and the third sub-layer 161, and the black matrix 17 located between the third sub-layer 161 and the fourth sub-layer 162, longitudinal sections of portions of the black matrix 17 each located between every two adjacent sub-pixels P are of a same shape or different shapes, the shape including a rectangle, a triangle, an arch, a trapezoid or an inverted trapezoid. The longitudinal section is perpendicular to a surface on which the substrate 11 is located.

In these embodiments, as shown in FIG. 2H, the second light extraction layer 16 has the single-layer structure, the black matrix 17 is located between the first light extraction layer 15 and the second light extraction layer 16, and the longitudinal section of the portion of the black matrix 17 located between every two adjacent sub-pixels P is in a shape of the rectangle. In this case, the eighth surface h is a portion enclosed by the dotted box in FIG. 2H, the included angle between the seventh surface g and the eighth surface h is 90 degrees. In a case where the longitudinal section of the portion of the black matrix 17 located between every two adjacent sub-pixels P is in a shape of the triangle, the included angle between the seventh surface g and the eighth surface h is a base angle of the triangle. As shown in FIG. 2L, the second light extraction layer 16 includes the third sub-layer 161 and the fourth sub-layer 162, the black matrix 17 is disposed between the third sub-layer 161 and the fourth sub-layer 162, and the longitudinal section of the portion of the black matrix 17 located between every two adjacent sub-pixels P is in a shape of the arch, which is a pattern consisting of a chord m and an arc opposite to the chord m. In this case, the included angle γ between the seventh surface g and the eighth surface h may be an angle between the chord m of the arch and a tangent LL′ through a point R, R being an endpoint of an arc of the arch. In a case where the longitudinal section of the portion of the black matrix 17 located between every two adjacent sub-pixels P is in a shape of the trapezoid, the included angle γ between the seventh surface g and the eighth surface h is a base angle of the trapezoid. In a case where the longitudinal section of the portion of the black matrix 17 located between every two adjacent sub-pixels P is in a shape of the inverted trapezoid, the included angle γ between the seventh surface g and the eighth surface h is a base angle of the inverted trapezoid.

In some embodiments, as shown in FIG. 2L, the second light extraction layer 16 includes the third sub-layer 161 and the fourth sub-layer 162, the black matrix 17 is disposed between the third sub-layer 161 and the fourth sub-layer 162, and the longitudinal section of the portion of the black matrix 17 located between every two adjacent sub-pixels P is in a shape of a semicircle. In this case, the included angle γ between the seventh surface g and the eighth surface h is 90 degrees.

In some embodiments, as shown in FIGS. 2F to 2L, the plurality of sub-pixels P further include at least one third sub-pixel P3, and the light conversion pattern 13 included in a respective one of the at least one third sub-pixel P3 is a third light conversion pattern 13_3. The third light conversion pattern 13_3 is configured to convert the light of the first color emitted by the light-emitting element 12 into light of a third color and emit the light of the third color. The first color, the second color and the third color are three primary colors. As shown in FIG. 6, the first light conversion pattern 13_1 and the third light conversion pattern 13_3 each include a third transparent substrate 132, and quantum dot light-emitting materials 133 dispersed in the third transparent substrate 132.

In these embodiments, the first color, the second color and the third color may be blue, red and green, respectively. In this case, the quantum dot light-emitting materials in the first light conversion pattern 13_1 and the quantum dot light-emitting materials in the third light conversion pattern 13_3 are red quantum dot light-emitting materials and green quantum dot light-emitting materials, respectively.

It is merely an example of a full-color display substrate here, and those skilled in the art could understand that the first color, the second color and the third color may be other colors, such as blue, yellow and white.

In some embodiments, as shown in FIG. 6, the first light conversion pattern 13_1 and the third light conversion pattern 13_3 each further include scattering particles 134 dispersed in a respective third transparent substrate 132. The scattering particles may scatter light, so as to improve a light-exit effect.

The third transparent substrate and the second transparent substrate may be made of a same material or different materials.

In some embodiments, a photoluminescence quantum yield of the quantum dot light-emitting material is greater than 70%, absorbance per micron of the quantum dot light-emitting material is greater than 0.1/μm, and light conversion efficiency of the quantum dot light-emitting material may be greater than 30%. Thus, it may further improve the light conversion efficiency.

In some optional embodiments, the photoluminescence quantum yield of the quantum dot light-emitting material is greater than 80%, the absorbance per micron of the quantum dot light-emitting material is greater than 0.2/μm, and the light conversion efficiency of the quantum dot light-emitting material may be greater than 35%.

In some embodiments, the quantum dot light-emitting materials may be, for example, cadmium-containing (Cd-containing) materials, such as CdSe and CdSeZn. Alternatively, the quantum dot light-emitting materials may be non-cadmium-containing (non-Cd-containing) materials, such as InP and perovskite.

In some embodiments, the scattering particles may be oxide nanoparticles, such as zirconia nanoparticles, titanium oxide nanoparticles and alumina nanoparticles.

The light conversion pattern 13 may be prepared by a method such as photolithography, imprinting or printing.

In some embodiments, a particle size of the oxide nanoparticle is less than or equal to 800 nm. Oxide nanoparticles with too large particle sizes are not conducive to the preparation using the printing processes.

In some embodiments, a doping ratio of the scattering particles is in a range of 5 wt % to 30 wt %, inclusive. The scattering particles may increase a scattering effect and improve the light-exit efficiency. With an increase of the doping ratio, the light-exit efficiency increases. However, if the doping ratio is too large, it is prone to an increase of haze of the panel and a decrease of clarity of the image.

In some optional embodiments, the doping ratio of the scattering particles is in a range of 10 wt % to 20 wt %, inclusive.

In some embodiments, as shown in FIGS. 2F to 2L, in a case where the light-emitting substrate 1 further includes the second light extraction layer 16, the light-emitting substrate 1 further includes a filter film 18. The filter film 18 is disposed on a side of the second light extraction layer 16 away from the substrate 11, and the filter film 18 includes a plurality of filter units 180. Each filter unit 180 is disposed in a region where a sub-pixel P is located. For a filter unit 180 located in a region where the second sub-pixel P2 is located, a difference between a peak value of a transmission spectrum of the filter unit 180 and a peak value of the light emitted by the light-emitting element 12 is not more than 5 nm, and a half-peak width of the transmission spectrum of the filter unit 180 is not less than a half-peak width of the light emitted by the light-emitting element 12. For a filter unit 180 located in a region where the first sub-pixel P1 is located, a difference between a peak value of a transmission spectrum of the filter unit 180 and a peak value of light exiting from the first light conversion pattern 13_1 is not more than 5 nm, and a half-peak width of the transmission spectrum of the filter unit 180 is not less than a half-peak width of the light exiting from the first light conversion pattern 13_1. For a filter unit located in a region where the third sub-pixel P3 is located, a difference between a peak value of a transmission spectrum of the filter unit 180 and a peak value of light exiting from the third light conversion pattern 13_3 is not more than 5 nm, and a half-peak width of the transmission spectrum of the filter unit 180 is not less than a half-peak width of the light exiting from the third light conversion pattern 13_3.

These embodiments show the case where the first sub-pixel P1, the second sub-pixel P2 and the third sub-pixel P3 are respectively the red sub-pixel R, the blue sub-pixel B and the green sub-pixel G. The filter units may be prepared by printing. The filter units 180 may reflect the external light and increase the transmittance. In addition, the filter units may also improve the light-exit efficiency.

In some embodiments, the light-emitting substrate 1 does not include the polarizer. The polarizer will reduce the light-exit efficiency of the light-emitting substrate. In addition, a device containing the quantum dot light-emitting materials will convert the polarized light to non-polarized light, which cannot play a role of reducing the reflectance. The black matrix 17 and the filter units 18 adopted in the embodiments of the present disclosure may function to reduce the reflectance.

Based on the above embodiments, in order to objectively evaluate technical effects of the technical solutions provided by the embodiments of the present disclosure, the technical solutions provided in the embodiments of the present disclosure will be illustratively described in detail with reference to comparative examples and experimental examples below.

In the following comparative examples and experimental examples, the light-emitting elements 12 are all OLED light-emitting elements that emit the blue light. Light-emitting function layers of the OLED light-emitting elements are made in a same material. The OLED light-emitting elements are all top-emission light-emitting elements.

### Comparative Example 1

as shown in FIG. 1A, in the comparative example 1, the light-emitting substrate 1 includes the substrate 11 that is provided thereon with the pixel driving circuits, and the plurality of light-emitting elements 12, the encapsulation layer 10 and the light conversion patterns 13 that are sequentially stacked in the direction away from the substrate 11. The light conversion patterns 13 include the first light conversion patterns 13_1, the second light conversion patterns 13_2 and the third light conversion patterns 13_3. The first light conversion patterns 13_1 and the third light conversion patterns 13_3 each include scattering particles and quantum dot light-emitting materials. The first light conversion pattern 13_1 includes red quantum dot light-emitting materials, the third light conversion pattern 13_3 includes green quantum dot light-emitting materials, and the second light conversion pattern 13_2 only includes the scattering particles.

### Experimental Example 1

as shown in FIG. 2A, in the experimental example 1, in addition to the light-emitting elements 12, the encapsulation layer 10 and the light conversion patterns 13 in the comparative example 1, the light-emitting substrate 1 further includes the first light extraction layer 15 that is disposed on light conversion patterns 13 and located in a region where the first light conversion patterns 13_1 and the third light conversion patterns 13_3 are located. The first light extraction layer 15 has the single-layer structure, and the thickness of the first light extraction layer 15 is 5 nm. The first light extraction layer 15 includes the polymer and the cholesteric liquid crystals fixed in the polymer. The cholesteric liquid crystals may include the nematic liquid crystals and the chiral auxiliaries. For example, the cholesteric liquid crystals may be the cholesteric liquid crystals having the left-helical structures.

### Experimental Example 2

as shown in FIG. 2C, in the experimental example 2, the light-emitting substrate 1 also includes the first light extraction layer 15 that is disposed on the light conversion patterns and located in the region where the first light conversion pattern 13_1 and the third light conversion pattern 13_3 are located, but the difference is that the first light extraction layer 15 includes the first sub-layer 151 and the second sub-layer 152 that are stacked. The first sub-layer and the second sub-layer both have slope angles with 90 degrees and have a same coverage area. The thickness of the first sub-layer is 5 nm, and the thickness of the second sub-layer is 5 nm. The first sub-layer 151 has a same material as the first light extraction layer in the experimental example 1. The second sub-layer 152 includes the polymer and the cholesteric liquid crystals fixed in the polymer, the cholesteric liquid crystals may include nematic liquid crystals and chiral auxiliaries (e.g., the cholesteric liquid crystals having the right-helical structures).

### Comparative Example 2

as shown in FIG. 2M, in the comparative example 2, the light-emitting substrate 1 is a light-emitting substrate in which the second light extraction layer 16 is formed on the light conversion patterns in the comparative example 1, the second light extraction layer 16 includes the third sub-layer 161 and the fourth sub-layer 162 that are arranged sequentially, the black matrix 17 disposed between the third sub-layer 161 and the fourth sub-layer 162, and filter units 180 disposed on a side of the fourth sub-layer 162 away from the substrate 11. The optical parameters of all the filter units 180 satisfy the optical parameters disclosed in the above embodiments, and the longitudinal section of the black matrix 17 is in the shape of the semicircle.

### Experimental Example 3

as shown in FIG. 2J, in the experimental example 3, in addition to the first sub-layer 151 and the second sub-layer 152 in the experimental example 2, the light-emitting substrate 1 further includes the second light extraction layer 16, the black matrix 17, and the filter units 180 that are in the comparative example 2. Structures of the second light extraction layer 16, the black matrix 17, and the filter units 180 are substantially the same as those in the comparative example 2.

Optical densities (ODs, OD being a unit of optical density, i.e., absorbance A) and external quantum efficiency (EQE) of the first light conversion patterns 13_1 and the third light conversion patterns 13_3 in the comparative example 1, and optical densities and external quantum efficiency of first light conversion pattern 13_1 and the third light conversion pattern 13_3 each without nanoparticles added thereto are tested, and results are obtained as shown in table 1 below.

TABLE 1

| | First light | First light | Third light | Third light |
|---|---|---|---|---|
| | conversion | conversion | conversion | conversion |
| | pattern | pattern | pattern | pattern |
| Name | (OD) | (EQE) | (OD) | (EQE) |
| Nanoparticles | 115% | 330% | 157% | 330% |
| added | | | | |
| (comparative | | | | |
| example 1) | | | | |
| No | 100% | 100% | 100% | 100% |
| nanoparticles | | | | |
| added | | | | |

It can be seen from Table 1 that, compared with a light conversion pattern without nanoparticles added, the nanoparticles are added to the first light conversion pattern 13_1 and the third light conversion pattern 13_3 adopted in the embodiments of the present disclosure, which may increase the absorbance of the first light conversion pattern 13_1 and the third light conversion pattern 13_3, thereby improving the light conversion efficiency of the first light conversion pattern 13_1 and the third light conversion pattern 13_3. For example, the external quantum efficiency of both the first light conversion pattern 13_1 and the third light conversion pattern 13_3 are increased by 3.3 times.

Light-exit efficiency of the light-emitting substrates 1 obtained in the comparative example 1 and 2 and the experimental examples 1 to 3, and reflectance of the light-emitting substrates 1 for the external light are tested, and results are obtained as shown in Table 2 below.

Reflectance of the light-emitting substrates for the external light is data obtained by testing the light-emitting substrates in a dark state (i.e., in a non-display state) irradiated under natural light that is simulated using an ultraviolet (UV) spectrometer.

TABLE 2

| | Light-exit efficiency | Light-exit efficiency | Reflectance to |
|---|---|---|---|
| Name | Red sub-pixel | Green sub-pixel | external light |
| Comparative | 100% | 100% | 100% |
| example 1 | | | |
| Comparative | 101% | 101% | 24.2% |
| example 2 | | | |
| Experimental | 103% | 104.6% | 93.1% |
| example 1 | | | |
| Experimental | 109.4% | 111.3% | 86.8% |
| example 2 | | | |
| Experimental | 121.1% | 122.8% | 21.7% |
| example 3 | | | |

It can be seen from Table 2 that, compared with the comparative example 1, the light-exit efficiency of the red sub-pixel and the light-exit efficiency of the green sub-pixel are both enhanced to a certain extent in the experimental example 1. It can be seen that by providing the first light extraction layer 15 having the single-layer structure in the region where the red sub-pixel and the green sub-pixel are located, blue light can be reflected, which may improve the light conversion efficiency of the blue light, and thus improve the light-exit efficiency. Compared with the comparative example 1, the light-exit efficiency of the red sub-pixel and the light-exit efficiency of the green sub-pixel are also both enhanced to a certain extent in the experimental example 2. In addition, the light-exit efficiency of the red sub-pixel and the light-exit efficiency of the green sub-pixel are higher in the experimental example 2 than the experimental example 1. It indicates that by providing the first light extraction layer 15 having a double-layer structure in the region where the red sub-pixel and the green sub-pixel are located, the reflectance to the blue light may be improved, thereby further improving the light-exit efficiency of blue light and improving the light-exit efficiency. Compared with the comparative example 1, the reflectance to the external light decreases, and the light-exit efficiency slightly increases in the comparative example 2, which indicates that by adding the second light extraction layer 16, the black matrix 17 and the filter units 180, the brightness in the front viewing direction may be improved to a certain extent, but the improvement effect is limited, and the reflectance of the panel may be greatly reduced. The second light extraction layer 16, the black matrix 17 and the filter units 180 are added in the experimental example 3 base on the experimental example 2. Due to the cooperative action of the first light extraction layer 15, the second light extraction layer 16, the black matrix 17, the filter units 180, etc., it may improve the light-exit efficiency to a greatest extent, reduce the reflectance of the panel and reduce the color crosstalk, which has an unexpected effect and may greatly improve the display effect of the panel.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A light-emitting substrate, comprising:
a substrate;
a plurality of sub-pixels disposed on the substrate, each sub-pixel including a light-emitting element disposed on the substrate and a light conversion pattern disposed on a light-exit side of the light-emitting element, the light-emitting element being configured to emit light of a first color;
the plurality of sub-pixels including at least one first sub-pixel, a light conversion pattern included in a respective one of the at least one first sub-pixel being a first light conversion pattern, and the first light conversion pattern being configured to convert the light of the first color emitted by a light-emitting element located in a same sub-pixel as the first light conversion pattern into light of a second color;
a first light extraction layer disposed on a side of the first light conversion pattern away from the light-emitting element, and at least located in a region where the at least one first sub-pixel is located; the first light extraction layer including at least one first transparent substrate and optically active substances added in each first transparent substrate, the optically active substances being selected from materials that are capable of selectively reflecting the light of the first color; and
a second light extraction layer disposed on a side of the first light extraction layer away from the light-emitting element, a refractive index of the second light extraction layer being smaller than a refractive index of the first light extraction layer, and the second light extraction layer being configured to change an exit angle of light exiting from the first light extraction layer.

2. The light-emitting substrate according to claim 1, wherein
the first light extraction layer has a single-layer structure;
or
the first light extraction layer includes a first sub-layer and a second sub-layer that are sequentially stacked in a direction away from the light-emitting element; the first sub-layer and the second sub-layer each include the optically active substances, and chirality of the optically active substances included in the first sub-layer is opposite to chirality of the optically active substances included in the second sub-layer.

3. The light-emitting substrate according to claim 1, wherein
the optically active substances are liquid crystal materials; or the optically active substances include liquid crystal materials and chiral auxiliaries; and/or
the light-emitting element includes a light-emitting layer, the light-emitting layer includes a first light-emitting sub-layer, a charge generation layer and a second light-emitting sub-layer that are sequentially stacked in a direction away from the substrate; luminescence spectrums of the first light-emitting sub-layer and the second light-emitting sub-layer are both in a range of 400 nm to 500 nm, inclusive.

4. The light-emitting substrate according to claim 1, wherein
the first light extraction layer includes a first sub-layer and a second sub-layer, the first sub-layer includes a first transparent substrate and optically active substances added in the first transparent substrate, the second sub-layer includes another first transparent substrate and optically active substances added in the another first transparent substrate, the optically active substances included in the first sub-layer and the optically active substances included in the second sub-layer are each liquid crystal materials, and the first transparent substrate included in the first sub-layer and the another first transparent substrate included in the second sub-layer are made of a same material or different materials; or
the first light extraction layer includes the first sub-layer and the second sub-layer, the first sub-layer includes the first transparent substrate and the optically active substances added in the first transparent substrate, the second sub-layer includes the another first transparent substrate and the optically active substances added in the another first transparent substrate, the optically active substances included in the first sub-layer and the optically active substances included in the second sub-layer each include liquid crystal materials and chiral auxiliaries, the first transparent substrate included in the first sub-layer and the another first transparent substrate included in the second sub-layer are made of a same material or different materials, and liquid crystal materials included in the first sub-layer and liquid crystal materials included in the second sub-layer are same or different.

5. The light-emitting substrate according to claim 1, wherein
the plurality of sub-pixels further include at least one second sub-pixel, a light conversion pattern included in a respective one of the at least one second sub-pixel is a second light conversion pattern; the second light conversion pattern includes a second transparent substrate and scattering particles added in the second transparent substrate; and
the first light extraction layer has a single-layer structure, the first light extraction layer has a first pattern; a first region is located within an orthographic projection of the first pattern on the substrate, and the orthographic projection of the first pattern on the substrate is located outside a second region; or
the first light extraction layer includes the first sub-layer and the second sub-layer, the first sub-layer has a second pattern, and the second sub-layer has a third pattern; the first region is located within an orthographic projection of at least one of the second pattern and the third pattern on the substrate, and orthographic projections of the second pattern and the third pattern on the substrate are located outside the second region;
wherein the first region is a region where other sub-pixels in the plurality of sub-pixels except the at least one second sub-pixel are located, and the second region is a region where the at least one second sub-pixel is located.

6. The light-emitting substrate according to claim 1, wherein
the first light extraction layer includes a first sub-layer and a second sub-layer, and an orthographic projection of the first sub-layer on the substrate is located within an orthographic projection of the second sub-layer on the substrate.

7. The light-emitting substrate according to claim 1, wherein
the first light extraction layer has a single-layer structure, and the refractive index of the first light extraction layer is greater than or equal to a refractive index of at least one light conversion pattern in a region where the first light extraction layer is located; or
the first light extraction layer includes a first sub-layer and a second sub-layer, and refractive indices of both the first sub-layer and the second sub-layer are greater than or equal to the refractive index of the at least one light conversion pattern in the region where the first light extraction layer is located.

8. The light-emitting substrate according to claim 1, wherein
the first light extraction layer has a single-layer structure, the first light extraction layer includes a first surface proximate to the substrate, a second surface away from the substrate, and third surfaces each connected to the first surface and the second surface; an included angle between a third surface and the first surface is greater than or equal to 30 degrees and less than or equal to 150 degrees; or
the first light extraction layer includes a first sub-layer and a second sub-layer, the first sub-layer and the second sub-layer each include a fourth surface proximate to the substrate, a fifth surface away from the substrate, and sixth surfaces each connected to the fourth surface and the fifth surface, an included angle between a sixth surface of the first sub-layer and the fourth surface of the first sub-layer is greater than or equal to 30 degrees and less than or equal to 150 degrees, and an included angle between a sixth surface of the second sub-layer and the fourth surface of the second sub-layer is greater than or equal to 30 degrees and less than or equal to 150 degrees.

9. The light-emitting substrate according to claim 1, wherein
the second light extraction layer has a single-layer structure;
or,
the second light extraction layer includes a third sub-layer and a fourth sub-layer that are sequentially arranged in a direction away from the substrate, a refractive index of the third sub-layer is smaller than the refractive index of the first light extraction layer, and a refractive index of the fourth sub-layer is smaller than the refractive index of the third sub-layer.

10. The light-emitting substrate according to claim 9, wherein
the second light extraction layer has the single-layer structure, and the second light extraction layer is provided with a first protrusion thereon corresponding to a region between every two adjacent sub-pixels; the first protrusion is configured to change the exit angle of the light exiting from the first light extraction layer; or
the second light extraction layer includes the third sub-layer and the fourth sub-layer, and at least one of the third sub-layer and the fourth sub-layer is provided with a second protrusion thereon corresponding to the region between every two adjacent sub-pixels; the second protrusion is configured to change the exit angle of the light exiting from the first light extraction layer.

11. The light-emitting substrate according to claim 10, further comprising a black matrix, wherein
the second light extraction layer has the single-layer structure, and the black matrix is disposed between the first light extraction layer and the second light extraction layer, so that the second light extraction layer is provided with the first protrusion thereon corresponding to the region between every two adjacent sub-pixels;
or
the second light extraction layer includes the third sub-layer and the fourth sub-layer; the black matrix is disposed between the third sub-layer and the first light extraction layer, so that the third sub-layer is provided with the second protrusion thereon corresponding to the region between every two adjacent sub-pixels; or the black matrix is disposed between the third sub-layer and the fourth sub-layer, so that the fourth sub-layer is provided with the second protrusion thereon corresponding to the region between every two adjacent sub-pixels.

12. The light-emitting substrate according to claim 11, further comprising a pixel defining layer, wherein the pixel defining layer defines a plurality of openings, and each opening corresponds to a region where a sub-pixel is located;
an orthographic projection of the black matrix on the substrate is located within an orthographic projection of the pixel defining layer on the substrate, and an orthographic projection of a border of the black matrix on the substrate and an orthographic projection of a border of the pixel defining layer on the substrate have a space therebetween.

13. The light-emitting substrate according to claim 11, wherein
the second light extraction layer has the single-layer structure, a portion of the black matrix located between every two adjacent sub-pixels includes a seventh surface in contact with the first light extraction layer and an eighth surface in contact with the second light extraction layer, and an included angle between the seventh surface and the eighth surface is greater than 30 degrees; or
the second light extraction layer includes the third sub-layer and the fourth sub-layer, the black matrix is located between the third sub-layer and the first light extraction layer, the portion of the black matrix located between every two adjacent sub-pixels includes the seventh surface in contact with the first light extraction layer and the eighth surface in contact with the third sub-layer, and the included angle between the seventh surface and the eighth surface is greater than 30 degrees; or
the second light extraction layer includes the third sub-layer and the fourth sub-layer, the black matrix is located between the third sub-layer and the fourth sub-layer, the portion of the black matrix located between every two adjacent sub-pixels includes the seventh surface in contact with the third sub-layer and the eighth surface in contact with the fourth sub-layer, and the included angle between the seventh surface and the eighth surface is greater than 30 degrees.

14. The light-emitting substrate according to claim 11, wherein longitudinal sections of portions, of the black matrix, each located between every two adjacent sub-pixels are in a same shape or different shapes, and a shape is a rectangle, a triangle, an arch, a trapezoid or an inverted trapezoid; a longitudinal section is perpendicular to a surface where the substrate is located; and/or
for light with a wavelength in a range of 380 nm to 780 nm, inclusive, absorbance per micron of the black matrix is greater than 0.5/μm.

15. (canceled)

16. The light-emitting substrate according to claim 9, wherein
the second light extraction layer includes the third sub-layer and the fourth sub-layer, a difference between the refractive index of the third sub-layer and the refractive index of the fourth sub-layer is greater than 0.2; and/or
the second light extraction layer includes the third sub-layer and the fourth sub-layer, a thickness of the third sub-layer is greater than 3.5 μm, and a thickness of the fourth sub-layer is less than 2.5 μm.

17. (canceled)

18. The light-emitting substrate according to claim 1, wherein
the first light extraction layer has a single-layer structure; for light with a wavelength in a range of 400 nm to 500 nm, inclusive, a light transmittance of the first light extraction layer is in a range of 40% to 70%, inclusive; and for light with a wavelength greater than 500 nm, a light transmittance of the first light extraction layer is greater than 90%; or
the first light extraction layer includes a first sub-layer and a second sub-layer; for the light with the wavelength in the range of 400 nm to 500 nm, inclusive, light transmittances of the first sub-layer and the second sub-layer are both in a range of 40% to 70%, inclusive, and a light transmittance of at least one of the first sub-layer and the second sub-layer is greater than 50%; and for the light with the wavelength greater than 500 nm, light transmittances of the first sub-layer and the second sub-layer are both greater than 90%.

19. The light-emitting substrate according to claim 18, wherein
the first light extraction layer includes the first sub-layer and the second sub-layer, and a difference between a center wavelength of light transmitted by the first sub-layer and a center wavelength of light transmitted by the second sub-layer is less than 20 nm.

20. The light-emitting substrate according to claim 1, wherein
the plurality of sub-pixels further include at least one third sub-pixel, a light conversion pattern included in a respective one of the at least one third sub-pixel is a third light conversion pattern; the third light conversion pattern is configured to convert the light of the first color emitted by a light-emitting element located in a same sub-pixel as the third light conversion pattern into light of a third color; the first color, the second color and the third color are three primary colors; and
the first light conversion pattern and the third light conversion pattern each include a third transparent substrate and quantum dot light-emitting materials dispersed in a respective third transparent substrate; or the first light conversion pattern and the third light conversion pattern each include a third transparent substrate, and quantum dot light-emitting materials and scattering particles that are dispersed in the respective third transparent substrate.

21. (canceled)

22. The light-emitting substrate according to claim 20, further comprising
a filter film, wherein the filter film is disposed on a side of the second light extraction layer away from the substrate, the filter film includes a plurality of filter units, and each filter unit is disposed in a region where a sub-pixel is located;
the plurality of sub-pixels further include at least one second sub-pixel, a light conversion pattern included in a respective one of the at least one second sub-pixel is a second light conversion pattern;
for a filter unit located in a region where a second sub-pixel is located, a difference between a peak value of a transmission spectrum of the filter unit and a peak value of light emitted by a light-emitting element included in the second sub-pixel is not more than 5 nm, and a half-peak width of the transmission spectrum of the filter unit is not less than a half-peak width of the light emitted by the light-emitting element included in the second sub-pixel;
for another filter unit located in a region where a first sub-pixel is located, a difference between a peak value of a transmission spectrum of the another filter unit and a peak value of light exiting from the first light conversion pattern is not more than 5 nm, and a half-peak width of the transmission spectrum of the another filter unit is not less than a half-peak width of the light exiting from the first light conversion pattern;
for yet another filter unit located in a region where a third sub-pixel is located, a difference between a peak value of a transmission spectrum of the yet another filter unit and a peak value of light exiting from the third light conversion pattern is not more than 5 nm, and a half-peak width of the transmission spectrum of the yet another filter unit is not less than a half-peak width of the light exiting from the third light conversion pattern.

23. (canceled)

24. A light-emitting device, comprising the light-emitting substrate according to claim 1.
